(19) United States
(12) Patent Application Publication
(10) Pub. No.: US 2025/0393260 A1
(43) Pub. Date: Dec. 25, 2025

(54) SEMICONDUCTOR DEVICE

(71) Applicant: Samsung Electronics Co., Ltd., Suwon-si (KR)

(72) Inventors: Jin A Kim, Suwon-si (KR); Dong Hoon Hwang, Suwon-si (KR); Jae Ho Jeon, Suwon-si (KR); Ji Soo Park, Suwon-si (KR)

(21) Appl. No.: 19/073,776

(22) Filed: Mar. 7, 2025

(30) Foreign Application Priority Data
Jun. 25, 2024 (KR) 10-2024-0082430

(51) Int. Cl. H10D 30/83; H10D 30/00; H10D 30/01; H10D 30/43; H10D 62/10; H10D 62/13; H10D 64/23; H10D 64/27; H10D 84/01; H10D 84/83

(52) U.S. Cl. CPC H10D 30/832; H10D 30/43; H10D 30/502; H10D 62/121; H10D 62/151; H10D 64/256; H10D 64/518; H10D 84/83138; H10D 30/014; H10D 30/0191; H10D 84/0153

(57) ABSTRACT

A semiconductor device includes a lower interlayer insulating layer, a first plurality of bottom nanosheets, a first plurality of upper nanosheets, an upper isolation layer between the first plurality of bottom nanosheets and the first plurality of upper nanosheets, a first bottom gate electrode on the lower interlayer insulating layer, a first upper gate electrode on an upper surface of the first bottom gate electrode, and a first active cut that extends into each of the first bottom gate electrode and the first plurality of bottom nanosheets in the vertical direction and is on an upper surface of the lower interlayer insulating layer, where the first active cut is spaced apart from the first upper gate electrode in the vertical direction, and where the first active cut at least partially overlaps each of the first upper gate electrode and the first plurality of upper nanosheets in the vertical direction.

### CROSS-REFERENCE TO RELATED APPLICATION

This application claims priority from Korean Patent Application No. 10-2024-0082430 filed on Jun. 25, 2024 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device. Specifically, the present disclosure relates to a semiconductor device including a MBCFET™ (Multi-Bridge Channel Field Effect Transistor).

### BACKGROUND

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they are easy to scale. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

Aspects of the present disclosure provide a semiconductor device with improved integration due to reduced area of cell region in a structure in which a plurality of upper nanosheets are stacked on a plurality of bottom nanosheets.

The aspects of the present disclosure are not limited to those mentioned above and another aspect which is not mentioned may be clearly understood by those skilled in the art from the description below.

According to some embodiments of the present disclosure, there is provided a semiconductor device, comprising a lower interlayer insulating layer that extends in each of a first horizontal direction and a second horizontal direction that intersects the first horizontal direction; a first plurality of bottom nanosheets stacked and spaced apart from each other in a vertical direction that is perpendicular to the first horizontal direction and the second horizontal direction, where the first plurality of bottom nanosheets are on the lower interlayer insulating layer; a first plurality of upper nanosheets that are spaced apart from the first plurality of bottom nanosheets in the vertical direction, where the first plurality of upper nanosheets are stacked and spaced apart from each other in the vertical direction; an upper isolation layer between an uppermost nanosheet of the first plurality of bottom nanosheets and a lowermost nanosheet of the first plurality of upper nanosheets; a first bottom gate electrode that extends in the second horizontal direction and is on the lower interlayer insulating layer, where the first bottom gate electrode at least partially surrounds the first plurality of bottom nanosheets; a first upper gate electrode that extends in the second horizontal direction and is on an upper surface of the first bottom gate electrode, where the first upper gate electrode is spaced apart from the first bottom gate electrode in the vertical direction, and where the first upper gate electrode at least partially surrounds the first plurality of upper nanosheets; and a first active cut that extends into each of the first bottom gate electrode and the first plurality of bottom nanosheets in the vertical direction and is on an upper surface of the lower interlayer insulating layer, where the first active cut is spaced apart from the first upper gate electrode in the vertical direction, and where the first active cut at least partially overlaps each of the first upper gate electrode and the first plurality of upper nanosheets in the vertical direction.

According to some embodiments of the present disclosure, there is provided a semiconductor device, comprising a lower interlayer insulating layer; a first plurality of bottom nanosheets that are stacked and spaced apart from each other in a vertical direction that is perpendicular to an upper surface of the lower interlayer insulating layer and are on the lower interlayer insulating layer; a second plurality of bottom nanosheets that are stacked and spaced apart from each other in the vertical direction and are on the lower interlayer insulating layer, where the second plurality of bottom nanosheets are spaced apart from the first plurality of bottom nanosheets in a first horizontal direction that is perpendicular to the vertical direction; a first plurality of upper nanosheets that are spaced apart from the first plurality of bottom nanosheets in the vertical direction, where the first plurality of upper nanosheets are stacked and spaced apart from each other in the vertical direction; a second plurality of upper nanosheets that are spaced apart from the second plurality of bottom nanosheets in the vertical direction, where the second plurality of upper nanosheets are stacked and spaced apart from each other in the vertical direction, and where the second plurality of upper nanosheets are spaced apart from the first plurality of upper nanosheets in the first horizontal direction; a first upper gate electrode that extends in a second horizontal direction that intersects the first horizontal direction, where the first upper gate electrode at least partially surrounds the first plurality of upper nanosheets; a second upper gate electrode that extends in the second horizontal direction, where the second upper gate electrode is spaced apart from the first upper gate electrode in the first horizontal direction, and where the second upper gate electrode at least partially surrounds the second plurality of upper nanosheets; a first active cut that extends into the first plurality of bottom nanosheets in the vertical direction and is on the upper surface of the lower interlayer insulating layer, where the first active cut is spaced apart from the first upper gate electrode in the vertical direction, and where the first active cut at least partially overlaps each of the first upper gate electrode and the first plurality of upper nanosheets in the vertical direction; and a gate cut that extends in the first horizontal direction and is on a sidewall of each of the first upper gate electrode and the second upper gate electrode, where the gate cut is in contact with the sidewall of each of the first upper gate electrode and the second upper gate electrode.

According to some embodiments of the present disclosure, there is provided a semiconductor device, comprising a lower interlayer insulating layer that extends in each of a first horizontal direction and a second horizontal direction that intersects the first horizontal direction; a plurality of bottom nanosheets that are stacked and spaced apart from each other in a vertical direction that is perpendicular to the first horizontal direction and the second horizontal direction, where the plurality of bottom nanosheets are on the lower interlayer insulating layer; a plurality of upper nanosheets that are spaced apart from the plurality of bottom nanosheets in the vertical direction, where the plurality of upper nanosheets are stacked and spaced apart from each other in the vertical direction; an upper isolation layer between an uppermost nanosheet of the plurality of bottom nanosheets and a lowermost nanosheet of the plurality of upper nanosheets; a bottom gate electrode that extends in the second horizontal direction and is on the lower interlayer insulating layer, where the bottom gate electrode at least partially surrounds the plurality of bottom nanosheets; an upper gate electrode that extends in the second horizontal direction and is on an upper surface of the bottom gate electrode, where the upper gate electrode is spaced apart from the bottom gate electrode in the vertical direction, and where the upper gate electrode at least partially surrounds the plurality of upper nanosheets; a bottom capping pattern that is between the lower interlayer insulating layer and the bottom gate electrode, where the bottom capping pattern is in contact with a bottom surface of the bottom gate electrode; an active cut that extends into each of the bottom capping pattern, the bottom gate electrode and the plurality of bottom nanosheets in the vertical direction, where the active cut is on an upper surface of the lower interlayer insulating layer, where the active cut is spaced apart from the upper gate electrode in the vertical direction, where the active cut at least partially overlaps each of the upper gate electrode and the plurality of upper nanosheets in the vertical direction, and where a bottom surface of the active cut is coplanar with a bottom surface of the bottom capping pattern; a gate isolation layer that is between an upper surface of the active cut and a bottom surface of the upper gate electrode and is on sidewalls of the upper isolation layer; a first gate cut that extends in the first horizontal direction and is on a first sidewall of the upper gate electrode; and a second gate cut that extends in the first horizontal direction and is on a second sidewall of the upper gate electrode opposite to the first sidewall of the upper gate electrode, where the first sidewall and the second sidewall of the active cut in are in contact with each of the first gate cut and the second gate cut, respectively, and where a width of the upper surface of the active cut in the first horizontal direction is less than a width of the bottom surface of the active cut in the first horizontal direction.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5 to 51 are intermediate stage diagrams for explaining methods of fabricating semiconductor devices according to some embodiments of the present disclosure;

FIG. 52 is a layout diagram for explaining a semiconductor device according to some other embodiments of the present disclosure;

FIG. 53 is a cross-sectional view taken along line D-D′ in FIG. 52;

FIG. 54 is a layout diagram for explaining a semiconductor device according to another several embodiments of the present disclosure;

FIG. 55 is a cross-sectional view taken along line E-E′ of FIG. 54;

FIG. 56 is a cross-sectional view taken along line F-F′ of FIG. 54;

FIG. 57 is a layout diagram for explaining a semiconductor device according to some other embodiments of the present disclosure;

FIG. 58 is a cross-sectional view taken along line G-G′ of FIG. 57; and

FIG. 59 is a cross-sectional view taken along line H-H′ of FIG. 57.

### DETAILED DESCRIPTION OF THE EMBODIMENTS

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

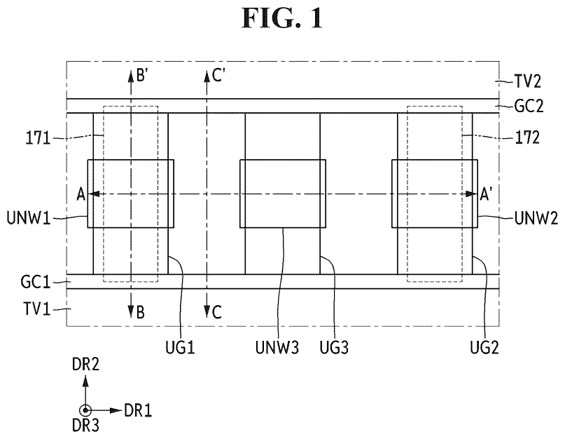

Hereinafter, the semiconductor device according to some embodiments of the present disclosure will be described with reference to FIGS. 1 to 4.

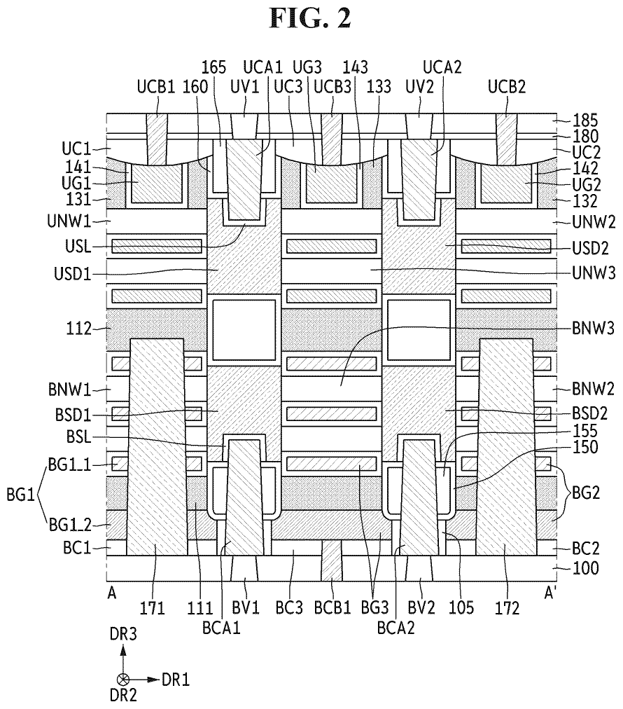

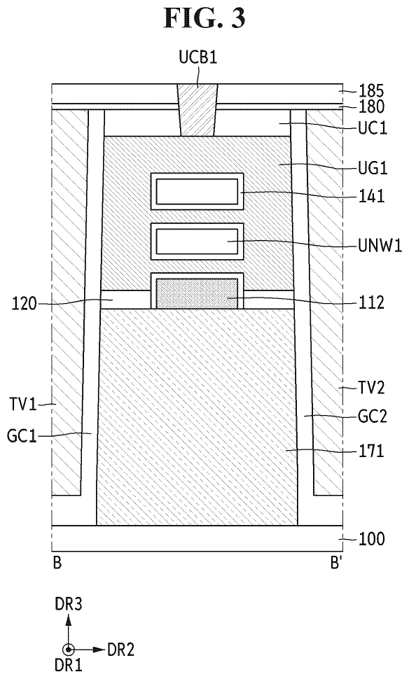

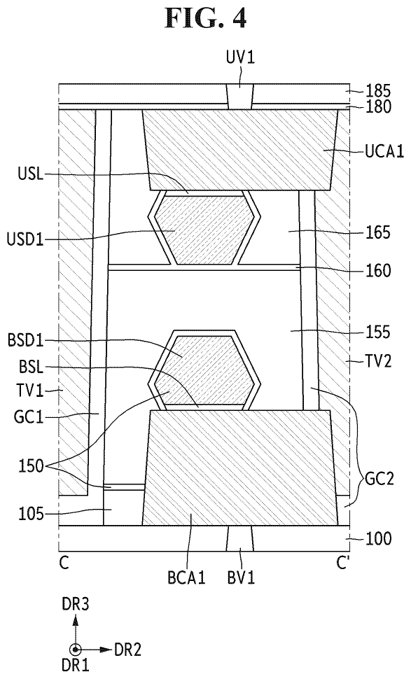

FIG. 1 is a layout diagram for explaining the semiconductor device according to some embodiments of the present disclosure. FIG. 2 is a cross-sectional view taken along line A-A′ of FIG. 1. FIG. 3 is a cross-sectional view taken along the line B-B′ of FIG. 1. FIG. 4 is a cross-sectional view taken along line C-C′ of FIG. 1.

Referring to FIGS. 1 to 4, a semiconductor device according to some embodiments of the present disclosure includes a first lower interlayer insulating layer 100, a second lower interlayer insulating layer 105, first to third plurality of bottom nanosheets BNW1, BNW2, BNW3, first to third plurality of upper nanosheets UNW1, UNW2, UNW3, a bottom isolation layer 111, an upper isolation layer 112, first to third bottom gate electrodes BG1, BG2, BG3, first to third upper gate electrodes UG1, UG2, UG3, gate isolation layer 120, first to third gate spacers 131, 132, 133, first to third gate insulating layers 141, 142, 143, first to third bottom capping patterns BC1, BC2, BC3, first to third upper capping patterns UC1, UC2, UC3, first and second bottom source/drain regions BSD1, BSD2, first and second upper source/drain regions USD1, USD2, a first etch stop layer 150, a first upper interlayer insulating layer 155, a second etch stop layer 160, a second upper interlayer insulating layer 165, first and second gate cuts GC1, GC2, first and second through vias TV1, TV2, first and second active cuts 171, 172, and first and second bottom source/drain contacts BCA1, BCA2, first and second upper source/drain contacts UCA1, UCA2, bottom silicide layer BSL, upper silicide layer USL, first bottom gate contact BCB1, first to third upper gate contacts UCB1, UCB2, UCB3, a third etch stop layer 180, a third upper interlayer insulating layer 185, first and second bottom vias BV1, BV2, and first and second upper vias UV1, UV2.

The first lower interlayer insulating layer 100 may include, for example, at least one of silicon oxide, silicon nitride, silicon oxynitride, and/or a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, and/or combinations thereof, but the present disclosure is not limited thereto.

Hereinafter, each of a first horizontal direction DR1 and a second horizontal direction DR2 may be defined as a direction parallel to an upper surface of the first lower interlayer insulating layer 100. The second horizontal direction DR2 may be defined as a direction different from and/or intersecting the first horizontal direction DR1. That is, the first lower interlayer insulating layer 100 may extend in each of the first horizontal direction DR1 and the second horizontal direction DR2. A vertical direction DR3 may be defined as a direction perpendicular to each of the first horizontal direction DR1 and the second horizontal direction DR2. That is, the vertical direction DR3 may be defined as a direction vertical to the upper surface of the first lower interlayer insulating layer 100.

Each of the first to third plurality of bottom nanosheets BNW1, BNW2, BNW3 may be disposed on the upper surface of the first lower interlayer insulating layer 100. Each of the first to third plurality of bottom nanosheets BNW1, BNW2, BNW3 may be spaced apart from the upper surface of the first lower interlayer insulating layer 100 in the vertical direction DR3. The third plurality of bottom nanosheets BNW3 may be spaced apart from the first plurality of bottom nanosheets BNW1 in the first horizontal direction DR1. The second plurality of bottom nanosheets BNW2 may be spaced apart from the third plurality of bottom nanosheets BNW3 in the first horizontal direction DR1. That is, the third plurality of bottom nanosheets BNW3 may be disposed between the first plurality of bottom nanosheets BNW1 and the second plurality of bottom nanosheets BNW2.

Each of the first to third plurality of bottom nanosheets BNW1, BNW2, BNW3 may include a plurality of nanosheets stacked in the vertical direction DR3 and spaced apart from each other. In FIG. 2, each of the first to third plurality of bottom nanosheets BNW1, BNW2, BNW3 is shown as including two nanosheets stacked in the vertical direction DR3, but this is for convenience of explanation. In some other embodiments, each of the first to third plurality of bottom nanosheets BNW1, BNW2, BNW3 may include three or more nanosheets stacked in the vertical direction DR3. For example, each of the first to third plurality of bottom nanosheets BNW1, BNW2, BNW3 may include silicon (Si). In some other embodiments, each of the first to third plurality of bottom nanosheets BNW1, BNW2, BNW3 may include silicon germanium (SiGe).

The first plurality of upper nanosheets UNW1 may be disposed on the first plurality of bottom nanosheets BNW1. The first plurality of upper nanosheets UNW1 may be spaced apart from the first plurality of bottom nanosheets BNW1 in the vertical direction DR3. The second plurality of upper nanosheets UNW2 may be disposed on the second plurality of bottom nanosheets BNW2. The second plurality of upper nanosheets UNW2 may be spaced apart from the second plurality of bottom nanosheets BNW2 in the vertical direction DR3. The second plurality of upper nanosheets UNW2 may be spaced apart from the first plurality of bottom nanosheets BNW1 in the first horizontal direction DR1. The third plurality of upper nanosheets UNW3 may be disposed on the third plurality of bottom nanosheets BNW3. The third plurality of upper nanosheets UNW3 may be spaced apart from the third plurality of bottom nanosheets BNW3 in the vertical direction DR3. The third plurality of upper nanosheets UNW3 may be disposed between the first plurality of upper nanosheets UNW1 and the second plurality of upper nanosheets UNW2. The third plurality of upper nanosheets UNW3 may be spaced apart from each of the first and second plurality of upper nanosheets UNW1, UNW2 in the first horizontal direction DR1.

Each of the first to third plurality of upper nanosheets UNW1, UNW2, UNW3 may include a plurality of nanosheets stacked in the vertical direction DR3 and spaced apart from each other. In FIG. 2, each of the first to third plurality of upper nanosheets UNW1, UNW2, UNW3 is shown as including two nanosheets stacked in the vertical direction DR3, but this is for convenience of explanation. In some other embodiments, each of the first to third plurality of upper nanosheets UNW1, UNW2, UNW3 may include three or more nanosheets stacked in the vertical direction DR3. For example, each of the first to third plurality of upper nanosheets UNW1, UNW2, UNW3 may include silicon (Si). In some other embodiments, each of the first to third plurality of top nanosheets UNW1, UNW2, UNW3 may include silicon germanium (SiGe).

The bottom isolation layer 111 may be disposed between the bottom surface of each of the first to third plurality of bottom nanosheets BNW1, BNW2, BNW3 and the upper surface of the first lower interlayer insulating layer 100. For example, the bottom surface of the bottom isolation layer 111 may be spaced apart from the upper surface of the first lower interlayer insulating layer 100 in the vertical direction DR3. For example, the bottom surfaces of the lowermost nanosheets of each of the first to third plurality of bottom nanosheets BNW1, BNW2, BNW3 may be spaced apart in the direction DR3 from the upper surface of the bottom isolation layer 111. For example, the bottom isolation layer 111 may overlap with each of the first to third plurality of bottom nanosheets BNW1, BNW2, BNW3 in the vertical direction DR3. For example, the sidewall of the bottom isolation layer 111 in the first horizontal direction DR1 may be aligned with the sidewall of each of the first to third plurality of bottom nanosheets BNW1, BNW2, BNW3 in the first horizontal direction DR1.

The upper isolation layer 112 may be disposed between each of the first to third plurality of bottom nanosheets BNW1, BNW2, BNW3 and each of the first to third plurality of upper nanosheets UNW1, UNW2, UNW3. For example, the upper isolation layer 112 may be disposed between the upper surface of the uppermost nanosheet of the first plurality of bottom nanosheets BNW1 and the bottom surface of the lowermost nanosheet of the first plurality of upper nanosheets UNW1. The upper isolation layer 112 may be disposed between the upper surface of the uppermost nanosheet of the second plurality of bottom nanosheets BNW2 and the bottom surface of the lowermost nanosheet of the second plurality of upper nanosheets UNW2. The upper isolation layer 112 may be disposed between the upper surface of the uppermost nanosheet of the third plurality of bottom nanosheets BNW3 and the bottom surface of the lowermost nanosheet of the third plurality of upper nanosheets UNW3.

For example, the bottom surface of the upper isolation layer 112 may be spaced apart from the upper surfaces of the uppermost nanosheets of each of the first to third plurality of bottom nanosheets BNW1, BNW2, BNW3 in the vertical direction DR3. Additionally, the bottom surfaces of the lowermost nanosheets of each of the first to third plurality of upper nanosheets UNW1, UNW2, UNW3 may be spaced apart from the upper surface of the upper isolation layer 112 in the vertical direction DR3. For example, the sidewall of the upper isolation layer 112 in the first horizontal direction DR1 may be aligned with the sidewall of each of the first to third plurality of bottom nanosheets BNW1, BNW2, BNW3 in the first horizontal direction DR1. Further, the sidewall of the upper isolation layer 112 in the first horizontal direction DR1 may be aligned with the sidewall of each of the first to third plurality of upper nanosheets UNW1, UNW2, UNW3 in the first horizontal direction DR1.

Each of the bottom isolation layer 111 and the upper isolation layer 112 may include an insulating material. For example, the bottom isolation layer 111 and the upper isolation layer 112 may include the same material. For example, each of the bottom isolation layer 111 and the upper isolation layer 112 may include at least one of silicon nitride (SiN), silicon oxycarbonitride (SiOCN), silicon boron carbonitride (SiBCN), silicon carbonitride (SiCN), silicon oxynitride (SiON), and/or combinations thereof. However, the present disclosure is not limited thereto.

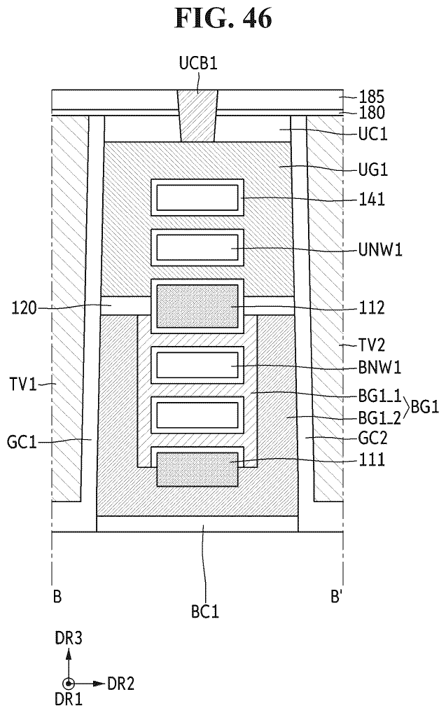

The first bottom gate electrode BG1 may extend in the second horizontal direction DR2 on the upper surface of the first lower interlayer insulating layer 100. The first bottom gate electrode BG1 may be spaced apart from the upper surface of the first lower interlayer insulating layer 100 in the vertical direction DR3. For example, the cross-sectional shape of the first bottom gate electrode BG1 taken along the second horizontal direction DR2 in the portion where the first active cut 171 is not disposed may be the same as the shape of the first bottom gate electrode BG1 shown in FIG. 46. For example, referring to FIG. 46, the first bottom gate electrode BG1 may at least partially surround each of the bottom isolation layer 111 and the first plurality of bottom nanosheets BNW1. For example, the first bottom gate electrode BG1 may at least partially surround at least a portion of the upper isolation layer 112.

Referring to FIG. 46, for example, the first bottom gate electrode BG1 may include a first conductive layer BG1_1 and a second conductive layer BG1_2. For example, the first conductive layer BG1_1 may be disposed on both sidewalls of a portion of the bottom isolation layer 111 in the second horizontal direction DR2, on both sidewalls of the first plurality of bottom nanosheets BNW1 in the second horizontal direction DR2, and on both sidewalls of a portion of the upper isolation layer 112 in the second horizontal direction DR2, respectively. For example, the first conductive layer BG1_1 may be disposed between each of the bottom isolation layer 111, the first plurality of bottom nanosheets BNW1, and the upper isolation layer 112.

Referring to FIG. 46, for example, the second conductive layer BG1_2 may be disposed on both sidewalls of the first conductive layer BG1_1 in the second horizontal direction DR2. The second conductive layer BG1_2 may be in contact with both sidewalls of the bottom isolation layer 111 in the second horizontal direction DR2 of the portion where the first conductive layer BG1_1 is not disposed. For example, the second conductive layer BG1_2 may be in contact with the bottom surface of the bottom isolation layer 111. For example, the uppermost surface of the second conductive layer BG1_2 may be formed on the same plane as (e.g., coplanar with) the uppermost surface of the first conductive layer BG1_1. For example, the lowermost surface of the second conductive layer BG1_2 may be formed lower than the lowermost surface of the first conductive layer BG1_1 relative to the upper surface of the first lower interlayer insulating layer 100 in the vertical direction DR3.

For example, the first conductive layer BG1_1 may include titanium aluminum carbide (TiAlC). For example, the second conductive layer BG1_2 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof.

The second bottom gate electrode BG2 may extend in the second horizontal direction DR2 on the upper surface of the first lower interlayer insulating layer 100. The second bottom gate electrode BG2 may be spaced apart from the first bottom gate electrode BG1 in the first horizontal direction DR1. The second bottom gate electrode BG2 may be spaced apart from the upper surface of the first interlayer insulating layer 100 in the vertical direction DR3. For example, the cross-sectional shape of the second bottom gate electrode BG2 taken along the second horizontal direction DR2 in the portion where the second active cut 172 is not disposed may be the same as the shape of the first bottom gate electrode BG1 shown in FIG. 46. For example, the second bottom gate electrode BG2 may include the first conductive layer BG1_1 and the second conductive layer BG1_2. For example, the second bottom gate electrode BG2 may at least partially surround each of the bottom isolation layer 111 and the second plurality of bottom nanosheets BNW2. For example, the second bottom gate electrode BG2 may surround at least a portion of the upper isolation layer 112.

The third bottom gate electrode BG3 may extend in the second horizontal direction DR2 on the upper surface of the first lower interlayer insulating layer 100. The third bottom gate electrode BG3 may be disposed between the first bottom gate electrode BG1 and the second bottom gate electrode BG2. The third bottom gate electrode BG3 may be spaced apart from each of the first and second bottom gate electrodes BG1, BG2 in the first horizontal direction DR1. The third bottom gate electrode BG3 may be spaced apart from the upper surface of the first lower interlayer insulating layer 100 in the vertical direction DR3. For example, the cross-sectional shape of the third bottom gate electrode BG3 taken along the second horizontal direction DR2 may be the same as the shape of the first bottom gate electrode BG1 shown in FIG. 46. For example, the third bottom gate electrode BG3 may include the first conductive layer BG1_1 and the second conductive layer BG1_2. For example, the third bottom gate electrode BG3 may surround each of the bottom isolation layer 111 and the third plurality of bottom nanosheets BNW3. For example, the third bottom gate electrode BG3 may surround at least a portion of the upper isolation layer 112.

The first upper gate electrode UG1 may extend in the second horizontal direction DR2 on the upper surface of the first bottom gate electrode BG1. The first upper gate electrode UG1 may be spaced apart from the first bottom gate electrode BG1 in the vertical direction DR3. The first upper gate electrode UG1 may at least partially surround the first plurality of upper nanosheets UNW1. For example, the first upper gate electrode UG1 may surround a portion of the upper isolation layer 112. The second upper gate electrode UG2 may extend in the second horizontal direction DR2 on the upper surface of the second bottom gate electrode BG2. The second upper gate electrode UG2 may be spaced apart from the second bottom gate electrode BG2 in the vertical direction DR3. The second upper gate electrode UG2 may be spaced apart from the first upper gate electrode UG1 in the first horizontal direction DR1. The second upper gate electrode UG2 may at least partially surround the second plurality of upper nanosheets UNW2. For example, the second upper gate electrode UG2 may surround a portion of the upper isolation layer 112. The third upper gate electrode UG3 may extend in the second horizontal direction DR2 on the upper surface of the third bottom gate electrode BG3. The third upper gate electrode UG3 may be spaced apart from the third bottom gate electrode BG3 in the vertical direction DR3. The third upper gate electrode UG3 may be disposed between the first upper gate electrode UG1 and the second upper gate electrode UG2. The third upper gate electrode UG3 may be spaced apart from each of the first and second upper gate electrodes UG1, UG2 in the first horizontal direction DR1. The third upper gate electrode UG3 may at least partially surround the third plurality of upper nanosheets UNW3. For example, the third upper gate electrode UG3 may surround a portion of the upper isolation layer 112.

For example, each of the first to third upper gate electrodes UG1, UG2, UG3 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof.

The gate isolation layer 120 may be disposed between the upper surface of the first active cut 171 and the bottom surface of the first upper gate electrode UG1 on both sidewalls of the upper isolation layer 112 in the second horizontal direction DR2. The gate isolation layer 120 may be disposed between the upper surface of the second active cut 172 and the bottom surface of the second upper gate electrode UG2 on both sidewalls of the upper isolation layer 112 in the second horizontal direction DR2. The gate isolation layer 120 may be disposed between the upper surface of the third bottom gate electrode BG3 and the third upper gate electrode UG3 on both sidewalls of the upper isolation layer 112 in the second horizontal direction DR2. The gate isolation layer 120 may include an insulating material. For example, the gate isolation layer 120 may include silicon oxide (SiO₂). However, the present disclosure is not limited thereto.

The first gate spacer 131 may be disposed on both sidewalls of the first upper gate electrode UG1 in the first horizontal direction DR1 on the upper surface of the uppermost nanosheet of the first plurality of upper nanosheets UNW1. The second gate spacer 132 may be disposed on both sidewalls of the second upper gate electrode UG2 in the first horizontal direction DR1 on the upper surface of the uppermost nanosheet of the second plurality of upper nanosheets UNW2. The third gate spacer 133 may be disposed on both sidewalls of the third upper gate electrode UG3 in the first horizontal direction DR1 on the upper surface of the uppermost nanosheet of the third plurality of upper nanosheets UNW3. For example, each of the first to third gate spacers 131, 132, 133 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and/or combinations thereof. However, the present disclosure is not limited thereto.

The first bottom source/drain region BSD1 may be disposed between the first plurality of bottom nanosheets BNW1 and the third plurality of bottom nanosheets BNW3. The first bottom source/drain region BSD1 may be in contact with the sidewall of each of the first and third plurality of bottom nanosheets BNW1, BNW3 in the first horizontal direction DR1. The second bottom source/drain region BSD2 may be disposed between the third plurality of bottom nanosheets BNW3 and the second plurality of bottom nanosheets BNW2. The second bottom source/drain region BSD2 may be in contact with the sidewall of each of the third and second plurality of bottom nanosheets BNW3, BNW2 in the first horizontal direction DR1.

The first upper source/drain region USD1 may be disposed on the first bottom source/drain region BSD1 between the first plurality of upper nanosheets UNW1 and the third plurality of upper nanosheets UNW3. The first upper source/drain region USD1 may be spaced apart from the first bottom source/drain region BSD1 in the vertical direction DR3. The first upper source/drain region USD1 may be in contact with the sidewall of each of the first and third plurality of upper nanosheets UNW1, UNW3 in the first horizontal direction DR1. The second upper source/drain region USD2 may be disposed on the second bottom source/drain region BSD2 between the third plurality of upper nanosheets UNW3 and the second plurality of upper nanosheets UNW2. The second upper source/drain region USD2 may be spaced apart from the second bottom source/drain region BSD2 in the vertical direction DR3. The second upper source/drain region USD2 may be in contact with the sidewall of each of the third and second plurality of upper nanosheets UNW3, UNW2 in the first horizontal direction DR1.

The first gate insulating layer 141 may be disposed between the first bottom gate electrode BG1 and the first plurality of bottom nanosheets BNW1. The first gate insulating layer 141 may be disposed between the first upper gate electrode UG1 and the first plurality of upper nanosheets UNW1. The first gate insulating layer 141 may be disposed between the first bottom gate electrode BG1 and the first bottom source/drain region BSD1. The first gate insulating layer 141 may be disposed between the first upper gate electrode UG1 and the first upper source/drain region USD1. The first gate insulating layer 141 may be disposed between the first bottom gate electrode BG1 and the bottom isolation layer 111. The first gate insulating layer 141 may be disposed between the first bottom gate electrode BG1 and the upper isolation layer 112. The first gate insulating layer 141 may be disposed between the first upper gate electrode UG1 and the upper isolation layer 112. The first gate insulating layer 141 may be disposed between the first upper gate electrode UG1 and the first gate spacer 131. The first gate insulating layer 141 may be disposed between the gate isolation layer 120 and the upper isolation layer 112.

The second gate insulating layer 142 may be disposed between the second bottom gate electrode BG2 and the second plurality of bottom nanosheets BNW2. The second gate insulating layer 142 may be disposed between the second upper gate electrode UG2 and the second plurality of upper nanosheets UNW2. The second gate insulating layer 142 may be disposed between the second bottom gate electrode BG2 and the second bottom source/drain region BSD2. The second gate insulating layer 142 may be disposed between the second upper gate electrode UG2 and the second upper source/drain region USD2. The second gate insulating layer 142 may be disposed between the second bottom gate electrode BG2 and the bottom isolation layer 111. The second gate insulating layer 142 may be disposed between the second bottom gate electrode BG2 and the upper isolation layer 112. The second gate insulating layer 142 may be disposed between the second upper gate electrode UG2 and the upper isolation layer 112. The second gate insulating layer 142 may be disposed between the second upper gate electrode UG2 and the second gate spacer 132.

The third gate insulating layer 143 may be disposed between the third bottom gate electrode BG3 and the third plurality of bottom nanosheets BNW3. The third gate insulating layer 143 may be disposed between the third upper gate electrode UG3 and the third plurality of upper nanosheets UNW3. The third gate insulating layer 143 may be disposed between the third bottom gate electrode BG3 and the first and second bottom source/drain regions BSD1, BSD2, respectively. The third gate insulating layer 143 may be disposed between the third upper gate electrode UG3 and the first and second upper source/drain regions USD1, USD2, respectively. The third gate insulating layer 143 may be disposed between the third bottom gate electrode BG3 and the bottom isolation layer 111. The third gate insulating layer 143 may be disposed between the third bottom gate electrode BG3 and the upper isolation layer 112. The third gate insulating layer 143 may be disposed between the third upper gate electrode UG3 and the upper isolation layer 112. The third gate insulating layer 143 may be disposed between the third upper gate electrode UG3 and the third gate spacer 133.

Each of the first to third gate insulating layers 141, 142, 143 may include at least one of silicon oxide, silicon oxynitride, silicon nitride, or a high-k material having a dielectric constant greater than silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other embodiments may include an NC (Negative Capacitance) FET utilizing a negative capacitor. For example, each of the first to third gate insulating layers 141, 142, 143 may include a ferroelectric material layer having ferroelectric properties and a paraelectric material layer having paraelectric properties.

The ferroelectric material layer may have negative capacitance, while the paraelectric material layer may have positive capacitance. For example, if two or more capacitors are connected in series, and the capacitance of each capacitor has a positive value, the total capacitance decreases compared to the capacitance of each individual capacitor. On the other hand, if at least one of the capacitances of the two or more capacitors connected in series has a negative value, the total capacitance may have a positive value and be greater than the absolute value of each individual capacitance.

When a ferroelectric material layer having negative capacitance and a paraelectric material layer having positive capacitance are connected in series, the total capacitance value of the ferroelectric material layer and the paraelectric material layer connected in series may be increased. Utilizing the increase in the total capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and/or lead zirconium titanium oxide. As an example, the hafnium zirconium oxide may be a material in which zirconium (Zr) is doped into hafnium oxide. In another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The type of dopant included in the ferroelectric material layer may vary depending on which ferroelectric material is included in the ferroelectric material layer.

When the ferroelectric material layer includes hafnium oxide, the dopant included in the ferroelectric material layer may include, for example, at least one of gadolinium (Gd), silicon (Si), zirconium (Zr), aluminum (Al), and/or yttrium (Y).

When the dopant is aluminum (Al), the ferroelectric material layer may include from 3 to 8 at % (atomic %) of aluminum. Here, the ratio of the dopant may be a ratio of aluminum to the sum of hafnium and aluminum.

When the dopant is silicon (Si), the ferroelectric material layer may include 2 to 10 at % of silicon. If the dopant is yttrium (Y), the ferroelectric material layer may include 2 to 10 at % of yttrium. If the dopant is gadolinium (Gd), the ferroelectric material layer may include 1 to 7 at % of gadolinium. If the dopant is zirconium (Zr), the ferroelectric material layer may include 50 to 80 at % of zirconium.

The paraelectric material layer may have paraelectric properties. The paraelectric material layer may include, for example, at least one of silicon oxide and/or a metal oxide having a high-k dielectric constant. The metal oxide included in the paraelectric material layer may include, for example, at least one of hafnium oxide, zirconium oxide, and/or aluminum oxide, but is not limited thereto.

The ferroelectric material layer and the paraelectric material layer may include the same material. The ferroelectric material layer may have ferroelectric properties, while the paraelectric material layer may not have ferroelectric properties. For example, if the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness that exhibits ferroelectric properties, the thickness of the ferroelectric material layer may vary depending on the ferroelectric material.

As an example, each of the first to third gate insulating layers 141, 142, 143 may include a single ferroelectric material layer. As another example, each of the first to third gate insulating layers 141, 142, 143 may include a plurality of ferroelectric material layers spaced apart from each other. Each of the first to third gate insulating layers 141, 142, 143 may have a stacked layer structure in which the plurality of ferroelectric material layers and the plurality of paraelectric material layers are alternately stacked.

The first bottom capping pattern BC1 may be disposed between the upper surface of the first lower interlayer insulating layer 100 and the bottom surface of the first bottom gate electrode BG1. For example, the bottom surface of the first bottom capping pattern BC1 may be in contact with the upper surface of the first lower interlayer insulating layer 100. The upper surface of the first bottom capping pattern BC1 may be in contact with the bottom surface of the first bottom gate electrode BG1. The second bottom capping pattern BC2 may be disposed between the upper surface of the first lower interlayer insulating layer 100 and the bottom surface of the second bottom gate electrode BG2. For example, the bottom surface of the second bottom capping pattern BC2 may be in contact with the upper surface of the first lower interlayer insulating layer 100. The upper surface of the second bottom capping pattern BC2 may be in contact with the bottom surface of the second bottom gate electrode BG2. The third bottom capping pattern BC3 may be disposed between the upper surface of the first lower interlayer insulating layer 100 and the bottom surface of the third bottom gate electrode BG3. For example, the bottom surface of the third bottom capping pattern BC3 may be in contact with the upper surface of the first lower interlayer insulating layer 100. The upper surface of the third bottom capping pattern BC3 may be in contact with the bottom surface of the third bottom gate electrode BG3. For example, each of the first to third bottom capping patterns BC1, BC2, BC3 may include at least one of silicon nitride (SiN), silicon oxynitride (SiON), silicon oxide (SiO₂), silicon carbonitride (SiCN), silicon oxycarbonitride (SiOCN), and/or combinations thereof. However, the present disclosure is not limited thereto.

The second lower interlayer insulating layer 105 may be disposed on the upper surface of the first lower interlayer insulating layer 100. For example, the second lower interlayer insulating layer 105 may be in contact with the sidewall of each of the first to third bottom capping patterns BC1, BC2, BC3 in the first horizontal direction DR1. For example, the second lower interlayer insulating layer 105 may be in contact with the sidewall of the second conductive layer BG1_2 of each of the first to third bottom gate electrodes BG1, BG2, BG3 in the first horizontal direction DR1. For example, the upper surface of the second lower interlayer insulating layer 105 may be formed lower than the bottom surface of the bottom isolation layer 111 relative to the upper surface of the first lower interlayer insulating layer 100 in the vertical direction DR3. For example, the second lower interlayer insulating layer 105 may include at least one of silicon oxide, silicon nitride, silicon oxynitride, and/or a low-k material.

The first etch stop layer 150 may be disposed along the upper surface of the second lower interlayer insulating layer 105, the sidewall of the bottom isolation layer 111, the bottom surface and upper surface of each of the first and second bottom source/drain regions BSD1, BSD2, and the sidewall of each of the first and second bottom source/drain regions BSD1, BSD2 in the second horizontal direction DR2. For example, the first etch stop layer 150 may be in contact with the sidewall of the upper isolation layer 112. For example, the first etch stop layer 150 may be formed conformally. For example, the first etch stop layer 150 may include at least one of aluminum oxide, aluminum nitride, hafnium oxide, zirconium oxide, silicon oxide, silicon nitride, silicon oxynitride, and/or a low-k material.

The first upper interlayer insulating layer 155 may be disposed on the first etch stop layer 150. For example, the first upper interlayer insulating layer 155 may cover or at least partially overlap each of the first and second bottom source/drain regions BSD1, BSD2. For example, the upper surface of the first upper interlayer insulating layer 155 may be formed lower than the bottom surface of the lowermost nanosheets of each of the first to third plurality of upper nanosheets UNW1, UNW2, UNW3 relative to the upper surface of the first lower interlayer insulating layer 100 in the vertical direction DR3. For example, the first upper interlayer insulating layer 155 may include at least one of silicon oxide, silicon nitride, silicon oxynitride, and/or a low-k material.

The second etch stop layer 160 may be disposed along the upper surface of the first upper interlayer insulating layer 155, the bottom surface and upper surface of each of the first and second upper source/drain regions USD1, USD2, the sidewall of each of the first and second upper source/drain regions USD1, USD2 in the second horizontal direction DR2, and the sidewall of each of the first and third gate spacers 131, 132, 133. For example, the second etch stop layer 160 may be formed conformally. For example, the second etch stop layer 160 may include at least one of aluminum oxide, aluminum nitride, hafnium oxide, zirconium oxide, silicon oxide, silicon nitride, silicon oxynitride, and/or a low-k material.

The first upper capping pattern UC1 may extend in the second horizontal direction DR2 on the upper surface of each of the first upper gate electrode UG1, the first gate spacer 131, and the first gate insulating layer 141. The second upper capping pattern UC2 may extend in the second horizontal direction DR2 on the upper surface of each of the second upper gate electrode UG2, the second gate spacer 132, and the second gate insulating layer 142. The third upper capping pattern UC3 may extend in the second horizontal direction DR2 on the upper surface of each of the third upper gate electrode UG3, the third gate spacer 133, and the third gate insulating layer 143. For example, each of the first to third upper capping patterns UC1, UC2, UC3 may comprise at least one of silicon nitride (SiN), silicon oxynitride (SiON), silicon oxide (SiO₂), silicon carbonitride (SiCN), silicon oxycarbonitride (SiOCN), and/or combinations thereof. However, the present disclosure is not limited thereto.

The second upper interlayer insulating layer 165 may be disposed on the second etch stop layer 160. For example, the second upper interlayer insulating layer 165 may be in contact with the sidewall of each of the first to third upper capping patterns UC1, UC2, UC3. For example, the upper surface of the second upper interlayer insulating layer 165 may be formed on the same plane as the upper surface of each of the first to third upper capping patterns UC1, UC2, UC3. For example, the second upper interlayer insulating layer 165 may include at least one of silicon oxide, silicon nitride, silicon oxynitride, and/or a low-k material.

The first gate cut GC1 may extend in the first horizontal direction DR1 on the first sidewall of each of the first to third upper gate electrodes UG1, UG2, UG3 in the second horizontal direction DR2. The first gate cut GC1 may extend in the vertical direction DR3 from the upper surface of the first lower interlayer insulating layer 100 to the upper surface of the second upper interlayer insulating layer 165. The second gate cut GC2 may extend in the first horizontal direction DR1 on the second sidewall of each of the first to third upper gate electrodes UG1, UG2, UG3 opposite to the first sidewall of each of the first to third upper gate electrodes UG1, UG2, UG3 in the second horizontal direction DR2. The second gate cut GC2 may be spaced apart from the first gate cut GC1 in the second horizontal direction DR2. The second gate cut GC2 may extend in the vertical direction DR3 from the upper surface of the first lower interlayer insulating layer 100 to the upper surface of the second upper interlayer insulating layer 165. For example, each of the first to third bottom gate electrodes BG1, BG2, BG3, the gate isolation layer 120, and the first to third upper gate electrodes UG1, UG2, UG3 may be disposed between the first gate cut GC1 and the second gate cut GC2.

For example, the bottom surface of each of the first and second gate cuts GC1, GC2 may be in contact with the upper surface of the first lower interlayer insulating layer 100. For example, the sidewall of each of the first and second gate cuts GC1, GC2 in the second horizontal direction DR2 may be in contact with each of the first to third upper capping patterns UC1, UC2, UC3, the first to third upper gate electrodes UG1, UG2, UG3, and the gate isolation layer 120. Although not shown, the sidewall of each of the first and second gate cuts GC1, GC2 in the second horizontal direction DR2 may be in contact with each of the first to third bottom gate electrodes BG1, BG2, BG3. For example, the sidewall of each of the first and second gate cuts GC1, GC2 in the second horizontal direction DR2 may be in contact with each of the second lower interlayer insulating layer 105, the first etch stop layer 150, the first upper interlayer insulating layer 155, the second etch stop layer 160, and the second upper interlayer insulating layer 165. For example, the upper surface of each of the first and second gate cuts GC1, GC2 may be formed on the same plane as the upper surface of each of the second upper interlayer insulating layer 165 and the first to third upper capping patterns UC1, UC2, UC3. For example, each of the first and second gate cuts GC1, GC2 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and/or combinations thereof.

The first through via TV1 may be disposed inside the first gate cut GC1. The first through via TV1 may extend in the first horizontal direction DR1. The second through via TV2 may be disposed inside the second gate cut GC2. The second through via TV2 may extend in the first horizontal direction DR1. For example, the bottom surface of each of the first and second through vias TV1, TV2 may be spaced apart from the upper surface of the first lower interlayer insulating layer 100 in the vertical direction DR3. For example, the upper surface of each of the first and second through vias TV1, TV2 may be formed on the same plane as the upper surfaces of each of the first and second gate cuts GC1, GC2. Each of the first and second through vias TV1, TV2 may include a conductive material.

The first active cut 171 may penetrate or extend into each of the first bottom capping pattern BC1, the first bottom gate electrode BG1, the bottom isolation layer 111, and the first plurality of bottom nanosheets BNW1 in the vertical direction DR3 on the upper surface of the first lower interlayer insulating layer 100 and extend into the inside of the upper isolation layer 112. For example, the first active cut 171 may be disposed between the first gate cut GC1 and the second gate cut GC2. For example, the first active cut 171 may be disposed on the bottom surface of the first upper gate electrode UG1. The first upper gate electrode UG1 may be spaced apart from the upper surface of the first active cut 171 in the vertical direction DR3. For example, on both sidewalls of the upper isolation layer 112 in the second horizontal direction DR2, the gate isolation layer 120 may be disposed between the upper surface of the first active cut 171 and the bottom surface of the first upper gate electrode UG1. For example, the first active cut 171 may overlap with each of the first upper gate electrode UG1 and the first plurality of upper nanosheets UNW1 in the vertical direction DR3.

For example, both sidewalls of the first active cut 171 in the first horizontal direction DR1 may be in contact with each of the first bottom capping pattern BC1, the bottom isolation layer 111, the first bottom gate electrode BG1, the first plurality of bottom nanosheets BNW1, and a portion of the upper isolation layer 112. For example, both sidewalls of the first active cut 171 in the second horizontal direction DR2 may be in contact with each of the first and second gate cuts GC1, GC2. For example, the width of the upper surface of the first active cut 171 in the first horizontal direction DR1 is smaller than the width of the bottom surface of the first active cut 171 in the first horizontal direction DR1. Further, the width of the upper surface of the first active cut 171 in the second horizontal direction DR2 is smaller than the width of the bottom surface of the first active cut 171 in the second horizontal direction DR2.

The second active cut 172 may penetrate or extend into each of the second bottom capping pattern BC2, the second bottom gate electrode BG2, the bottom isolation layer 111, and the second plurality of bottom nanosheets BNW2 in the vertical direction DR3 on the upper surface of the first lower interlayer insulating layer 100 and extend into the inside of the upper isolation layer 112. For example, the second active cut 172 may be disposed between the first gate cut GC1 and the second gate cut GC2. For example, the second active cut 172 may be disposed on the bottom surface of the second upper gate electrode UG2. The second upper gate electrode UG2 may be spaced apart from the upper surface of the second active cut 172 in the vertical direction DR3. For example, on both sidewalls of the upper isolation layer 112 in the second horizontal direction DR2, the gate isolation layer 120 may be disposed between the upper surface of the second active cut 172 and the bottom surface of the second upper gate electrode UG2. For example, the second active cut 172 may overlap with each of the second upper gate electrode UG2 and the second plurality of upper nanosheets UNW2 in the vertical direction DR3.

For example, both sidewalls of the second active cut 172 in the first horizontal direction DR1 may be in contact with each of the second bottom capping pattern BC2, the bottom isolation layer 111, the second bottom gate electrode BG2, the second plurality of bottom nanosheets BNW2, and a portion of the upper isolation layer 112. For example, both sidewalls of the second active cut 172 in the second horizontal direction DR2 may be in contact with each of the first and second gate cuts GC1, GC2. For example, the width of the upper surface of the second active cut 172 in the first horizontal direction DR1 is smaller than the width of the bottom surface of the second active cut 172 in the first horizontal direction DR1. Additionally, the width of the upper surface of the second active cut 172 in the second horizontal direction DR2 is smaller than the width of the bottom surface of the second active cut 172 in the second horizontal direction DR2.

For example, the bottom surface of each of the first and second active cuts 171, 172 may be in contact with the upper surface of the first lower interlayer insulating layer 100. For example, the upper surface of each of the first and second active cuts 171, 172 may be formed higher than the upper surface of each of the first and second bottom source/drain regions BSD1, BSD2 relative to the upper surface of the first lower interlayer insulating layer 100 in the vertical direction DR3 (e.g., a distance between an upper surface of the first active cut 171 and the upper surface of the lower interlayer insulating layer 100 in the vertical direction DR3 is greater than a distance between an upper surface of the bottom source/drain region BSD1 and the upper surface of the lower interlayer insulating layer 100 in the vertical direction DR3). Further, the bottom surface of each of the first and second active cuts 171, 172 may be formed lower than the bottom surface of each of the first and second bottom source/drain regions BSD1, BSD2 relative to the upper surface of the first lower interlayer insulating layer 100 in the vertical direction DR3 (e.g., a distance between a bottom surface of the first active cut 171 and the upper surface of the lower interlayer insulating layer 100 in the vertical direction DR3 is less than a distance between a bottom surface of the bottom source/drain region BSD1 and the upper surface of the lower interlayer insulating layer 100 in the vertical direction DR3). For example, the bottom surface of each of the first and second active cuts 171, 172 may be formed on the same plane as the bottom surface of each of the first to third bottom capping patterns BC1, BC2, BC3 and the bottom surface of each of the first and second gate cuts GC1, GC2. For example, the upper surface of each of the first and second active cuts 171, 172 may be in contact with each of the upper isolation layer 112 and the gate isolation layer 120. Each of the first and second active cuts 171, 172 may include an insulating material. For example, each of the first and second active cuts 171, 172 may include at least one of silicon oxide (SiO₂), silicon nitride (SiN), silicon oxynitride (SiON), silicon carbonitride (SiCN), silicon oxycarbonitride (SiOCN), silicon oxycarbide (SiOC), and/or combinations thereof. However, the present disclosure is not limited thereto.

The first bottom source/drain contact BCA1 may be disposed at the lower portion of the first bottom source/drain region BSD1. The first bottom source/drain contact BCA1 may penetrate or extend into the second lower interlayer insulating layer 105, the first etch stop layer 150, and the first upper interlayer insulating layer 155 in the vertical direction DR3 and extend into the inside of the first bottom source/drain region BSD1. The first bottom source/drain contact BCA1 may be electrically connected to the first bottom source/drain region BSD1. For example, a portion of the upper surface of the first bottom source/drain contact BCA1 may be in contact with the second gate cut GC2. Further, one sidewall of the first bottom source/drain contact BCA1 in the second horizontal direction DR2 may be in contact with the second through via TV2.

The second bottom source/drain contact BCA2 may be disposed at the lower portion of the second bottom source/drain region BSD2. The second bottom source/drain contact BCA2 may penetrate or extend into the second lower interlayer insulating layer 105, the first etch stop layer 150, and the first upper interlayer insulating layer 155 in the vertical direction DR3 and extend into the inside of the second bottom source/drain region BSD2. The second bottom source/drain contact BCA2 may be electrically connected to the second bottom source/drain region BSD2. For example, the bottom surface of each of the first and second bottom source/drain contacts BCA1, BCA2 may be in contact with the upper surface of the first lower interlayer insulating layer 100. For example, the bottom surface of each of the first and second bottom source/drain contacts BCA1, BCA2 may be formed on the same plane as the bottom surface of each of the first and second active cuts 171, 172. However, the present disclosure is not limited thereto.

The first upper source/drain contact UCA1 may be disposed on the upper portion of the first upper source/drain region USD1. The first upper source/drain contact UCA1 may penetrate or extend into the second upper interlayer insulating layer 165 and the second etch stop layer 160 in the vertical direction DR3 and extend into the inside of the first upper source/drain region USD1. The first upper source/drain contact UCA1 may be electrically connected to the first upper source/drain region USD1. For example, a portion of the bottom surface of the first upper source/drain contact UCA1 may be in contact with the second gate cut GC2. Additionally, one sidewall of the first upper source/drain contact UCA1 in the second horizontal direction DR2 may be in contact with the second through via TV2. For example, the first upper source/drain contact UCA1 and the first bottom source/drain contact BCA1 may be electrically connected through the second through via TV2. However, the present disclosure is not limited thereto.

The second upper source/drain contact UCA2 may be disposed on the upper portion of the second upper source/drain region USD2. The second upper source/drain contact UCA2 may penetrate or extend into the second upper interlayer insulating layer 165 and the second etch stop layer 160 in the vertical direction DR3 and extend into the inside of the second upper source/drain region USD2. The second upper source/drain contact UCA2 may be electrically connected to the second upper source/drain region USD2. For example, the upper surface of each of the first and second upper source/drain contacts UCA1, UCA2 may be formed on the same plane as the upper surface of each of the first to third upper capping patterns UC1, UC2, UC3. However, the present disclosure is not limited thereto.

In FIGS. 2 and 4, each of the first and second bottom source/drain contacts BCA1, BCA2 and the first and second upper source/drain contacts UCA1, UCA2 is shown as being formed as a single layer, but the present disclosure is not limited thereto. In some other embodiments, each of the first and second bottom source/drain contacts BCA1, BCA2 and the first and second upper source/drain contacts UCA1, UCA2 may be formed as multiple layers. Each of the first and second bottom source/drain contacts BCA1, BCA2, the first and second upper source/drain contacts UCA1, UCA2 may include a conductive material.

The bottom silicide layer BSL may be disposed along the interface between the first bottom source/drain contact BCA1 and the first bottom source/drain region BSD1. Additionally, the bottom silicide layer BSL may be disposed along the interface between the second bottom source/drain contact BCA2 and the second bottom source/drain region BSD2. The upper silicide layer USL may be disposed along the interface between the first upper source/drain contact UCA1 and the first upper source/drain region USD1. Further, the upper silicide layer USL may be disposed along the interface between the second upper source/drain contact UCA2 and the second upper source/drain region USD2. For example, each of the bottom silicide layer BSL and the upper silicide layer USL may include a metal silicide material.

The third etch stop layer 180 may be disposed on the upper surface of each of the first to third upper capping patterns UC1, UC2, UC3, the first and second gate cuts GC1, GC2, the first and second through vias TV1, TV2, the first and second upper source/drain contacts UCA1, UCA2, and the second upper interlayer insulating layer 165. For example, the third etch stop layer 180 may be formed conformally. In FIGS. 2 to 4, the third etch stop layer 180 is shown being formed as a single layer, but the present disclosure is not limited thereto. In some other embodiments, the third etch stop layer 180 may be formed as multiple layers. For example, the third etch stop layer 180 may include at least one of aluminum oxide, aluminum nitride, hafnium oxide, zirconium oxide, silicon oxide, silicon nitride, silicon oxynitride, and/or a low-k material. The third upper interlayer insulating layer 185 may be disposed on the third etch stop layer 180. For example, the third upper interlayer insulating layer 185 may include at least one of silicon oxide, silicon nitride, silicon oxynitride, and/or a low-k material.

The first bottom gate contact BCB1 may penetrate or extend into the first lower interlayer insulating layer 100 and the third bottom capping pattern BC3 in the vertical direction DR3 and be connected to the third bottom gate electrode BG3. The first upper gate contact UCB1 may penetrate or extend into the third upper interlayer insulating layer 185, the third etch stop layer 180, and the first upper capping pattern UC1 in the vertical direction DR3 and be connected to the first upper gate electrode UG1. The second upper gate contact UCB2 may penetrate or extend into the third upper interlayer insulating layer 185, the third etch stop layer 180, and the second upper capping pattern UC2 in the vertical direction DR3 and be connected to the second upper gate electrode UG2. The third upper gate contact UCB3 may penetrate or extend into the third upper interlayer insulating layer 185, the third etch stop layer 180, and the third upper capping pattern UC3 in the vertical direction DR3 and be connected to the third upper gate electrode UG3. In FIGS. 1 and 2, each of the first bottom gate contact BCB1 and the first to third upper gate contacts UCB1, UCB2, UCB3 is shown as being formed as a single layer, but the present disclosure is not limited thereto. In some other embodiments, each of the first bottom gate contact BCB1, and the first to third upper gate contacts UCB1, UCB2, UCB3 may be formed as multiple layers. Each of the first bottom gate contact BCB1, and the first to third upper gate contacts UCB1, UCB2, UCB3 may include a conductive material.

The first bottom via BV1 may penetrate or extend into the first lower interlayer insulating layer 100 in the vertical direction DR3 and be connected to the first bottom source/drain contact BCA1. The second bottom via BV2 may penetrate or extend into the first lower interlayer insulating layer 100 in the vertical direction DR3 and be connected to the second bottom source/drain contact BCA2. The first upper via UV1 may penetrate or extend into the third upper interlayer insulating layer 185 and the third etch stop layer 180 in the vertical direction DR3 and be connected to the first upper source/drain contact UCA1. The second upper via UV2 may penetrate or extend into the third upper interlayer insulating layer 185 and the third etch stop layer 180 in the vertical direction DR3 and be connected to the second upper source/drain contact UCA2. Each of the first and second bottom vias BV1, BV2 and the first and second upper vias UV1, UV2 may include a conductive material.

In the semiconductor device having a structure in which a plurality of upper nanosheets are stacked on a plurality of bottom nanosheets, the area of a cell region may be increased if an active cut penetrating or extending into both the plurality of bottom nanosheets and the plurality of upper nanosheets is disposed. In the semiconductor device according to some embodiments of the present disclosure having a structure in which a plurality of upper nanosheets UNW1 are stacked on a plurality of bottom nanosheets BNW1, an active cut 171 penetrating or extending into the plurality of bottom nanosheets BNW1 may be disposed at the lower portion of each of the plurality of upper nanosheets UNW1 and the upper gate electrode UG1 surrounding the plurality of upper nanosheets UNW1. As a result, in the semiconductor device according to some embodiments of the present disclosure, the upper gate electrode UG1 disposed on the upper portion of the active cut 171 may be utilized as a gate electrode. Since the upper gate contact UCB1 connected to the upper gate electrode UG1 is disposed on the upper portion of the active cut 171, the area of a cell region may be reduced and thus the degree of integration of a semiconductor device may be improved.

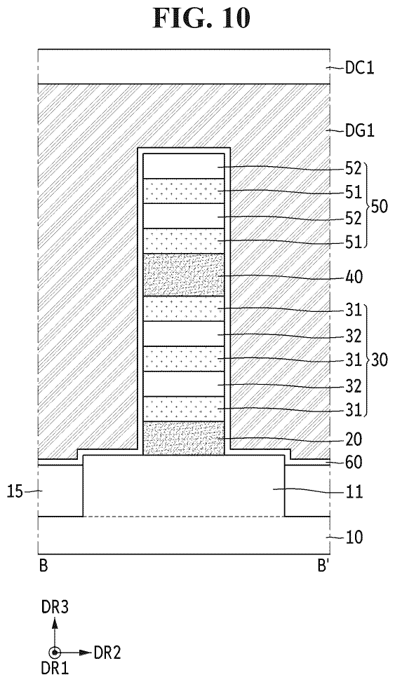

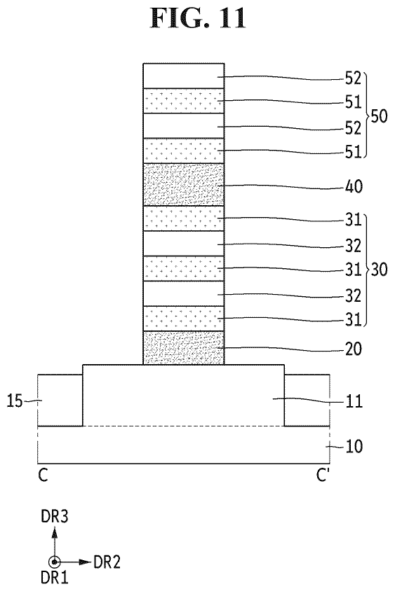

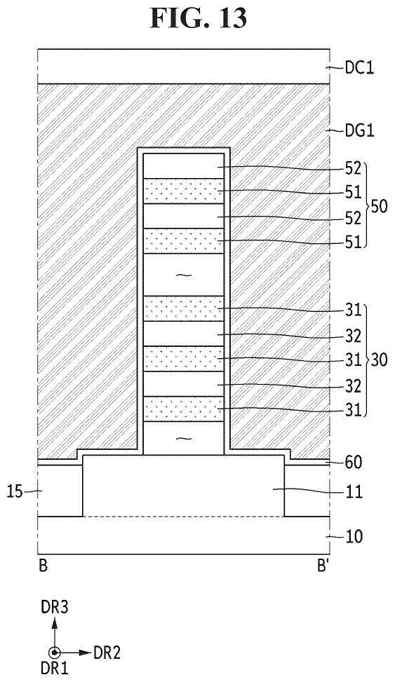

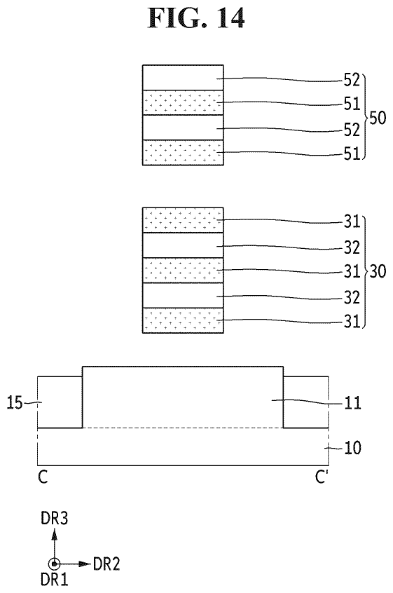

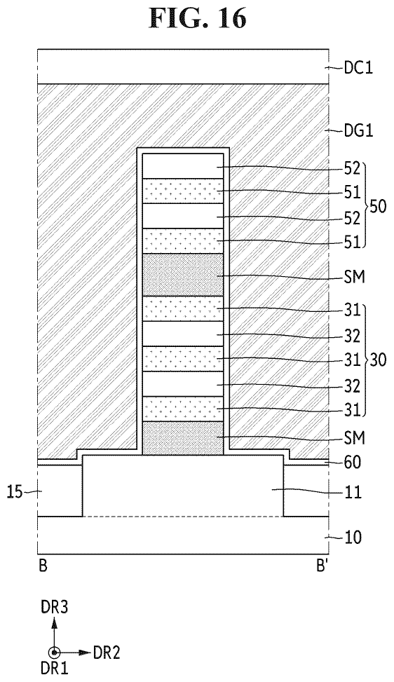

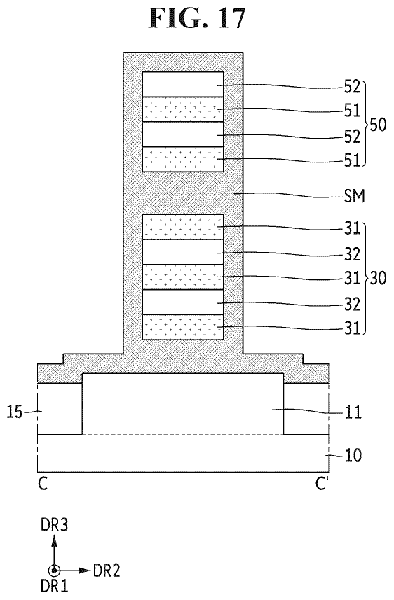

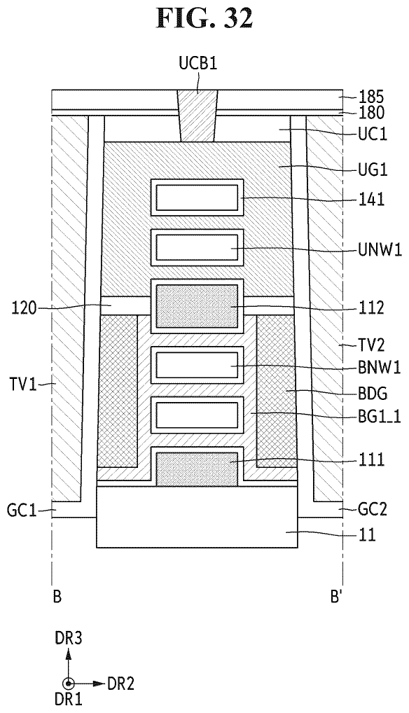

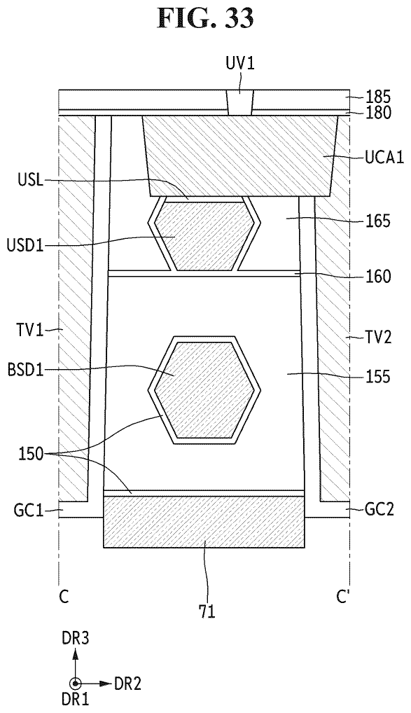

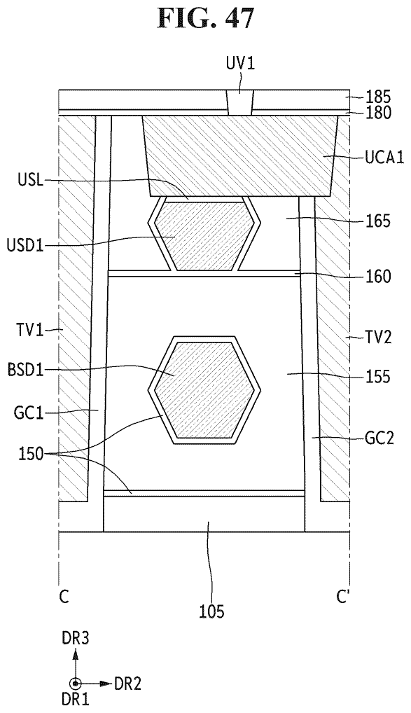

Hereinafter, with reference to FIGS. 2 to 51, the method of fabricating semiconductor device according to some embodiments of the present disclosure will be described.

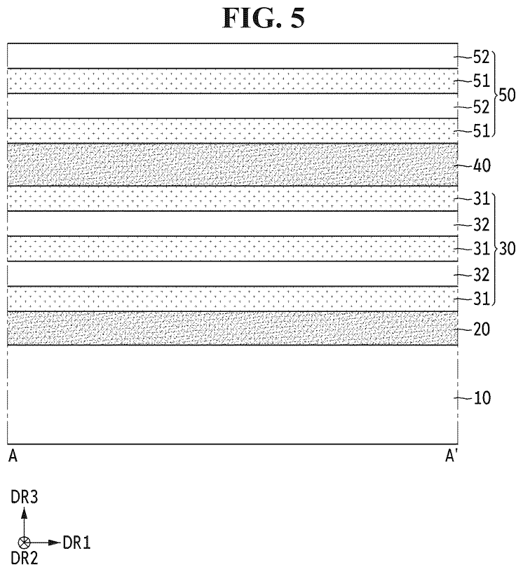

FIGS. 5 to 51 are intermediate stage diagrams for explaining the method of fabricating semiconductor device according to some embodiments of the present disclosure.

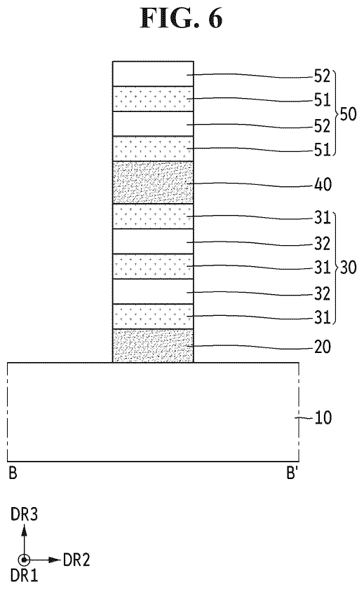

Referring to FIGS. 5 and 6, a first isolation material layer 20, a first laminated structure 30, a second isolation material layer 40, a second laminated structure 50 may be sequentially stacked on the substrate 10. The substrate 10 may be a silicon substrate or silicon-on-insulator (SOI). Alternatively, the substrate 10 may comprise silicon germanium, silicon germanium on insulator (SGOI), indium antimonide, lead tellurium compound, indium arsenide, indium phosphide, gallium arsenide, or gallium antimonide, but the present disclosure is not limited thereto.

The first isolation material layer 20 may be formed on the upper surface of the substrate 10. The first laminated structure 30 may include first sacrificial layers 31 and first semiconductor layers 32 alternately stacked on the upper surface of the first isolation material layer 20. For example, the first sacrificial layer 31 may be formed on each of the lowermost and uppermost portions of the first laminated structure 30. However, the present disclosure is not limited thereto. In some other embodiments, the first semiconductor layer 32 may be formed on the uppermost portion of the first laminated structure 30. The second isolation material layer 40 may be formed on the upper surface of the first laminated structure 30. The second laminated structure 50 may include the second sacrificial layers 51 and the second semiconductor layers 52 alternately stacked on the upper surface of the second isolation material layer 40. For example, the second sacrificial layer 51 may be formed at the lowermost portion of the second laminated structure 50 and the second semiconductor layer 52 may be formed on the uppermost portion of the second laminated structure 50. However, the present disclosure is not limited thereto. In some other embodiments, the second sacrificial layer 51 may also be formed on the uppermost portion of the second laminated structure 50.

For example, each of the first isolation material layer 20 and the second isolation material layer 40 may include silicon germanium (SiGe). For example, each of the first sacrificial layer 31 and the second sacrificial layer 51 may include silicon germanium (SiGe). For example, the concentration of germanium (Ge) included in each of the first isolation material layer 20 and the second isolation material layer 40 may be higher than the concentration of germanium (Ge) included in each of the first sacrificial layer 31 and the second sacrificial layer 51. For example, each of the first semiconductor layer 32 and the second semiconductor layer 52 may include silicon (Si). Subsequently, a portion of each of the second laminated structure 50, the second isolation material layer 40, the first laminated structure 30, and the first isolation material layer 20 may be etched. After such an etching process is performed, the sidewall in the second horizontal direction DR2 of each of the remaining second laminated structure 50, second isolation material layer 40, first laminated structure 30, and first isolation material layer 20 may have a continuous slope profile.

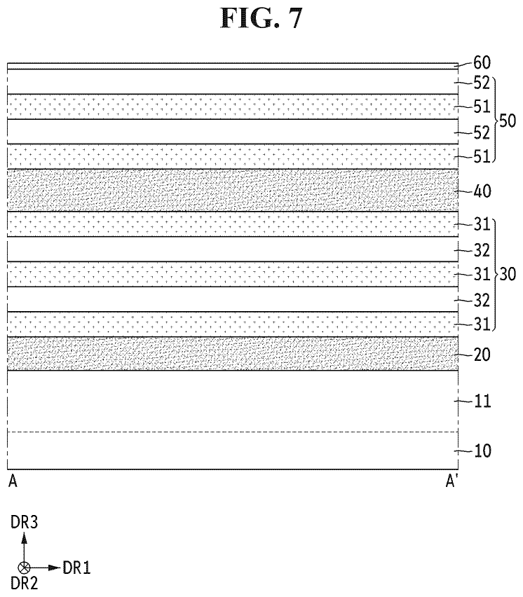

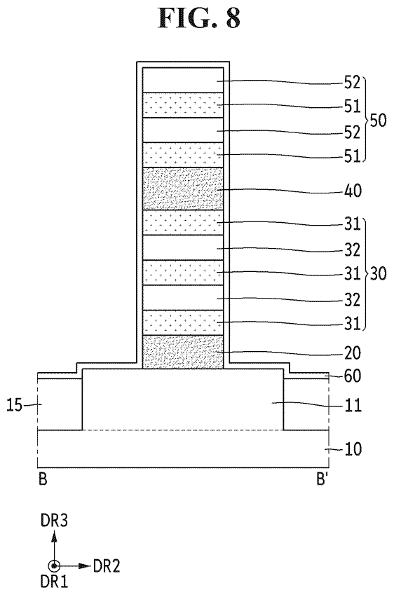

Referring to FIGS. 7 and 8, an active pattern 11 may be defined on the upper surface of the substrate 10 by etching a portion of the substrate 10. For example, after a spacer layer is formed on both sidewalls and upper surfaces in the second horizontal direction DR2 of the second laminated structure 50, the second isolation material layer 40, the first laminated structure 30, and the first isolation material layer 20, respectively, a portion of the substrate 10 may be etched using the spacer layer as a mask pattern. Subsequently, the spacer layer may be removed. Next, a field insulating layer 15 at least partially surrounding the sidewalls of the active pattern 11 on the upper surface of the substrate 10 may be formed. For example, the active pattern 11 may protrude or extend in the vertical direction DR3 above the upper surface of the field insulating layer 15. Subsequently, a pad oxide layer 60 may be formed to cover or overlap each of the field insulating layer 15, the first isolation material layer 20, the first laminated structure 30, the second isolation material layer 40, and the second laminated structure 50. For example, the pad oxide layer 60 may be formed conformally. The pad oxide layer 60 may include, for example, silicon oxide (SiO₂).

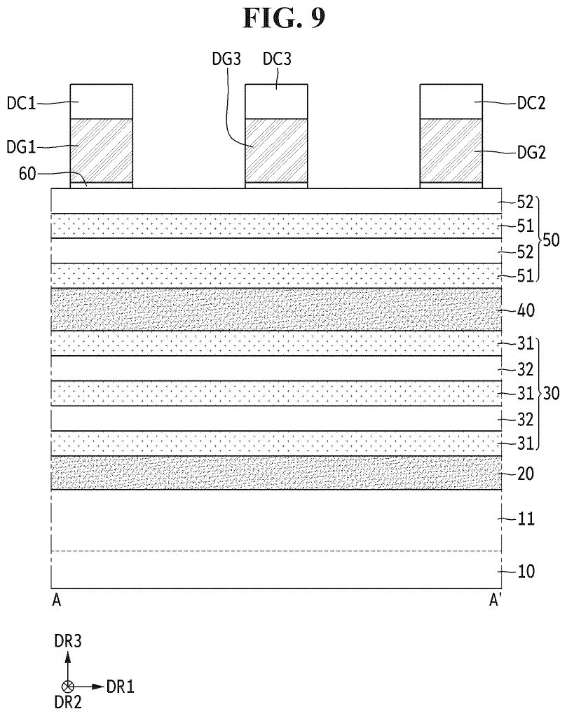

Referring to FIGS. 9 to 11, first to third dummy gates DG1, DG2, DG3 extending in the second horizontal direction DR2 may be formed on the field insulating layer 15 and the second laminated structure 50. The third dummy gate DG3 may be spaced apart from the first dummy gate DG1 in the first horizontal direction DR1. The second dummy gate DG2 may be spaced apart from the third dummy gate DG3 in the first horizontal direction DR1. Additionally, each of the first to third dummy capping patterns DC1, DC2, DC3 may be formed on each of the first to third dummy gates DG1, DG2, DG3. For example, the remaining portion of the pad oxide layer 60 except for the portion that overlaps with each of the first to third dummy gates DG1, DG2, DG3 in the vertical direction DR3 may be removed.

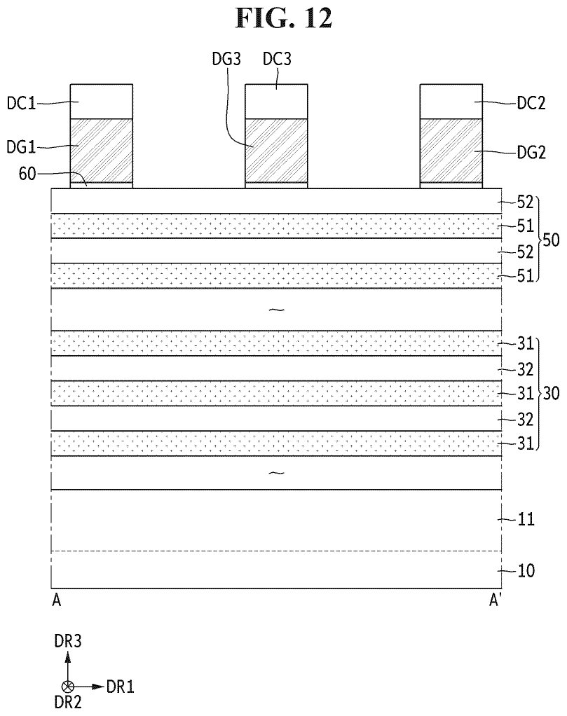

Referring to FIGS. 12 to 14, each of the first isolation material layer 20 (see FIGS. 9 to 11) and the second isolation material layer 40 (see FIGS. 9 to 11) may be etched. For example, each of the first isolation material layer 20 (see FIGS. 9 to 11) and the second isolation material layer 40 (see FIGS. 9 to 11) may be etched by a wet etching process.

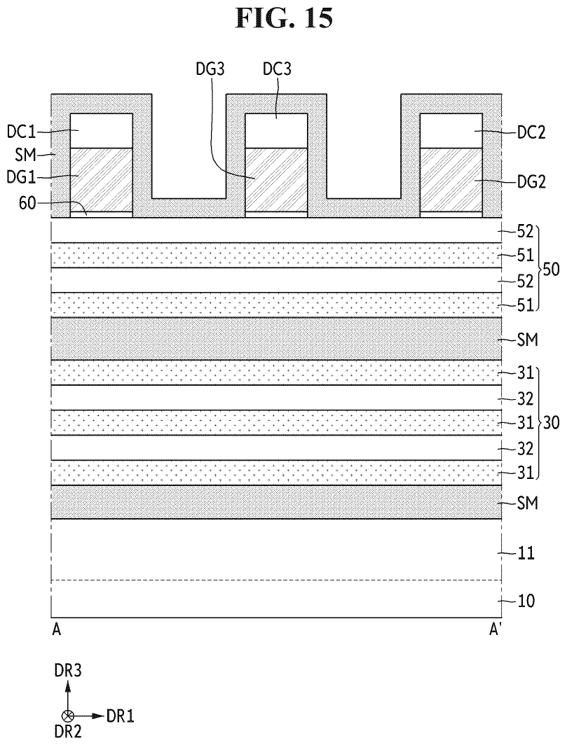

Referring to FIGS. 15 to 17, a spacer material layer SM may be formed to cover or overlap the sidewall of each of the first to third dummy gates DG1, DG2, DG3, the sidewall and upper surface of each of the first to third dummy capping patterns DC1, DC2, DC3, the first laminated structure 30, the second laminated structure 50, and the upper surface of the field insulating layer 15. The spacer material layer SM may at least partially fill the etched portions of each of the first isolation material layer 20 (see FIGS. 9 to 11) and the second isolation material layer 40 (see FIGS. 9 to 11). For example, the spacer material layer SM may be formed conformally. For example, the spacer material layer SM may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and/or combinations thereof.

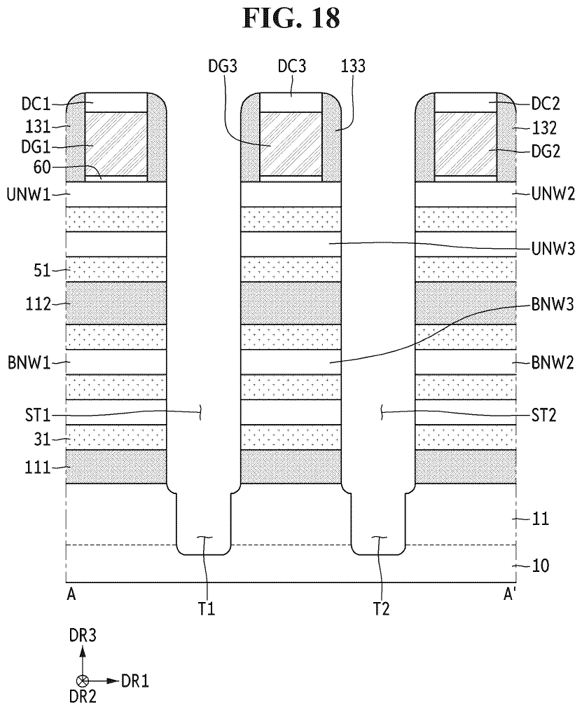

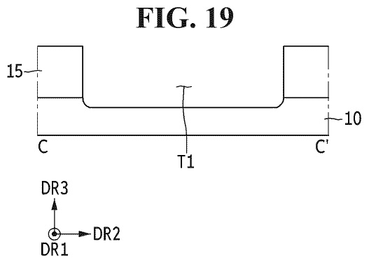

Referring to FIGS. 18 and 19, the first and second source/drain trenches ST1, ST2 may be formed by etching the first laminate structure 30 (see FIGS. 15 to 17), the second laminate structure 50 (see FIGS. 15 to 17), and the spacer material layer SM (see FIGS. 15 to 17) using the first and third dummy capping patterns DC1, DC2, DC3, and the first and third dummy gates DG1, DG2, DG3 as masks. For example, the first source/drain trench ST1 may be formed between the first dummy gate DG1 and the third dummy gate DG3. The second source/drain trench ST2 may be formed between the third dummy gate DG3 and the second dummy gate DG2.

Subsequently, the first sacrificial trench T1 may be formed at the lower portion of the first source/drain trench ST1, and the second sacrificial trench T2 may be formed at the lower portion of the second source/drain trench ST2. For example, each of the first and second sacrificial trenches T1, T2 may penetrate or extend into the active pattern 11 in the vertical direction DR3 and extend into the inside of the substrate 10. For example, the width of each of the first and second sacrificial trenches T1, T2 in the first horizontal direction DR1 may be smaller than the width of each of the first and second source/drain trenches ST1, ST2 in the first horizontal direction DR1.

For example, while each of the first and second source/drain trenches ST1, ST2 is being formed, the spacer material layer SM (see FIGS. 15 to 17) formed on the upper surface of each of the first to third dummy capping patterns DC1, DC2, DC3 and a portion of each of the first to third dummy capping patterns DC1, DC2, DC3 may be etched. The spacer material layer SM (see FIGS. 15 to 17) remaining on the sidewall of each of the first to third dummy gates DG1, DG2, DG3, and the remaining first to third dummy capping patterns DC1, DC2, DC3 may be defined as the first to third gate spacers 131, 132, 133.

For example, after each of the first and second source/drain trenches ST1, ST2 is formed, the first semiconductor layer 32 (see FIGS. 15 to 17) remaining at the lower portion of each of the first to third dummy gates DG1, DG2, DG3 may be defined as each of the first to third plurality of bottom nanosheets BNW1, BNW2, BNW3. Additionally, after each of the first and second source/drain trenches ST1, ST2 is formed, the second semiconductor layer 52 (see FIGS. 15 to 17) remaining at the lower portion of each of the first to third dummy gates DG1, DG2, DG3 may be defined as each of the first to third plurality of upper nanosheets UNW1, UNW2, UNW3.

For example, after each of the first and second source/drain trenches ST1, ST2 is formed, the spacer material layer SM (see FIGS. 15 to 17) remaining between the active pattern 11 and each of the first to third plurality of bottom nanosheets BNW1, BNW2, BNW3 may be defined as the bottom isolation layer 111. Additionally, after each of the first and second source/drain trenches ST1, ST2 is formed, the spacer material layer SM (see FIGS. 15 to 17) remaining between each of the first to third plurality of bottom nanosheets BNW1, BNW2, BNW3 and each of the first to third plurality of upper nanosheets UNW1, UNW2, UNW3 may be defined as the upper isolation layer 112.

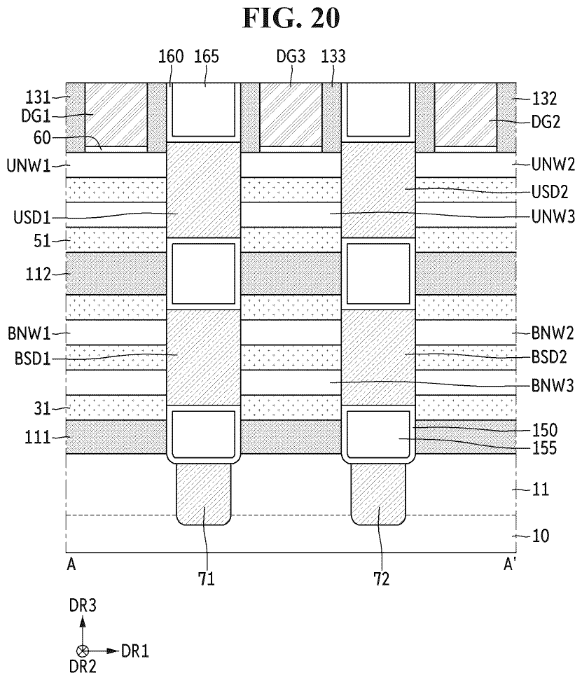

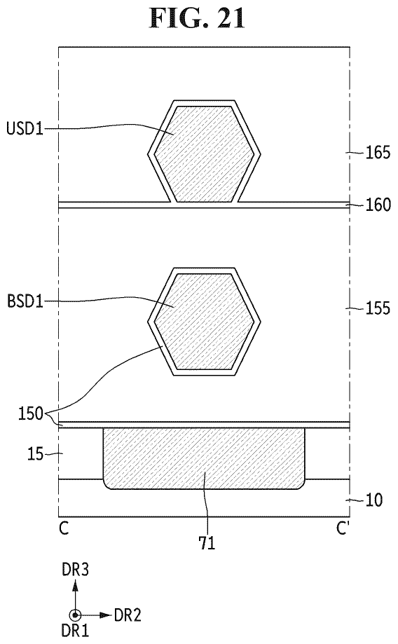

Referring to FIGS. 20 and 21, the first sacrificial pattern 71 may be formed inside the first sacrificial trench T1 (see FIGS. 18 and 19), and the second sacrificial pattern 72 may be formed inside the second sacrificial trench T2 (see FIGS. 18 and 19). Additionally, the first bottom source/drain region BSD1 may be formed between the first and third plurality of bottom nanosheets BNW1, BNW3 inside the first source/drain trench ST1 (see FIGS. 18 and 19), and the second bottom source/drain region BSD2 may be formed between the third and second plurality of bottom nanosheets BNW3, BNW2 inside the second source/drain trench ST2 (see FIGS. 18 and 19).

Subsequently, the first etch stop layer 150 may be formed on the upper surface of the field insulating layer 15, the upper surface of each of the first and second sacrificial patterns 71, 72, and the bottom surface, the upper surface and the sidewall in the second horizontal direction DR2 of each of the first and second bottom source/drain regions BSD1, BSD2. For example, the first etch stop layer 150 may be formed on the sidewall in the first horizontal direction DR1 of the upper isolation layer 112. Subsequently, the first upper interlayer insulating layer 155 may be formed on the first etch stop layer 150. For example, the upper surface of the first upper interlayer insulating layer 155 may be formed lower than the bottom surface of the lowermost nanosheets of each of the first to third plurality of upper nanosheets UNW1, UNW2, UNW3 relative to the upper surface of the substrate 10 in the vertical direction DR3.

Subsequently, the first upper source/drain region USD1 may be formed between the first and third plurality of upper nanosheets UNW1, UNW3 inside the first source/drain trench ST1 (see FIGS. 18 and 19), and the second upper source/drain region USD2 may be formed between the third and second plurality of upper nanosheets UNW3, UNW2 inside the second source/drain trench ST2 (see FIGS. 18 and 19). Subsequently, the second etch stop layer 160 may be formed on the upper surface of the first upper interlayer insulating layer 155, and the bottom surface, upper surface, and sidewall in the second horizontal direction DR2 of each of the first and second upper source/drain regions USD1, USD2. For example, the second etch stop layer 160 may also be formed on the sidewall in the first horizontal direction DR1 of each of the first to third gate spacers 131, 132, 133. Subsequently, a planarization process may be performed to expose the upper surface of each of the first to third dummy gates DG1, DG2, DG3.

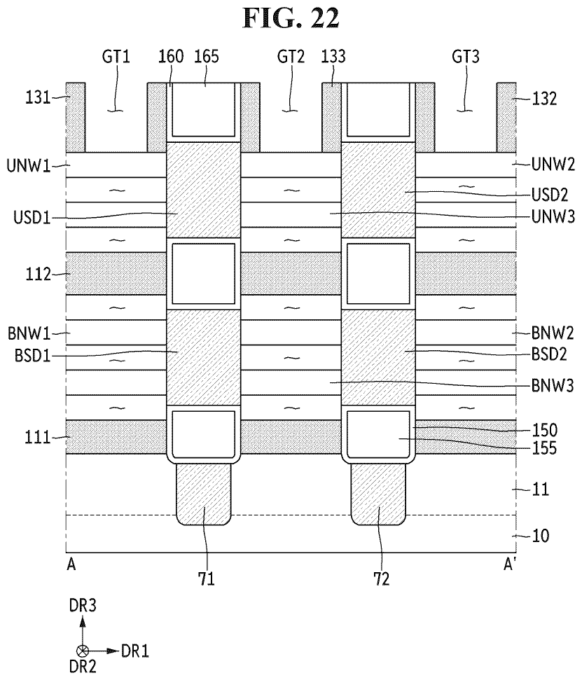

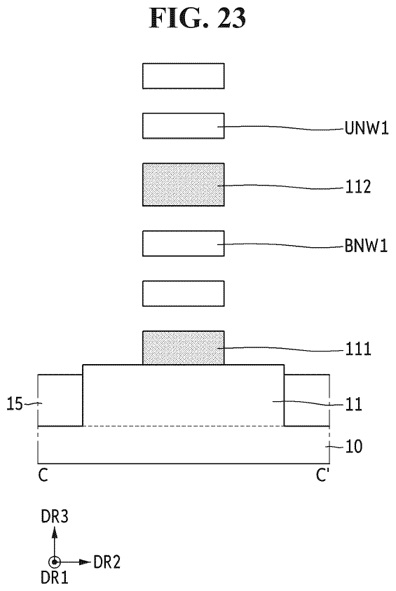

Referring to FIGS. 22 and 23, each of the first to third dummy gates DG1, DG2, DG3 (see FIG. 20), the pad oxide layer 60 (see FIG. 20), the first sacrificial layer 31 (see FIG. 20), and the second sacrificial layer 51 (see FIG. 20) may be etched. For example, the portion where each of the first dummy gate DG1 (see FIG. 20), the pad oxide layer 60 (see FIG. 20), the first sacrificial layer 31 (see FIG. 20), and the second sacrificial layer 51 (see FIG. 20) is etched may be defined as the first gate trench GT1. The portion where each of the second dummy gate DG2 (see FIG. 20), the pad oxide layer 60 (see FIG. 20), the first sacrificial layer 31 (see FIG. 20), and the second sacrificial layer 51 (see FIG. 20) is etched may be defined as the second gate trench GT2. The portion where each of the third dummy gate DG3 (see FIG. 20), the pad oxide layer 60 (see FIG. 20), the first sacrificial layer 31 (see FIG. 20), and the second sacrificial layer 51 (see FIG. 20) is etched may be defined as the third gate trench GT3.

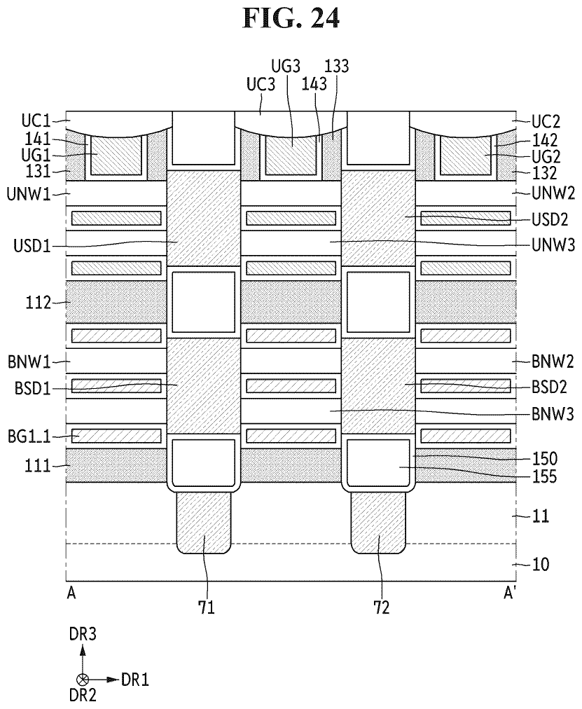

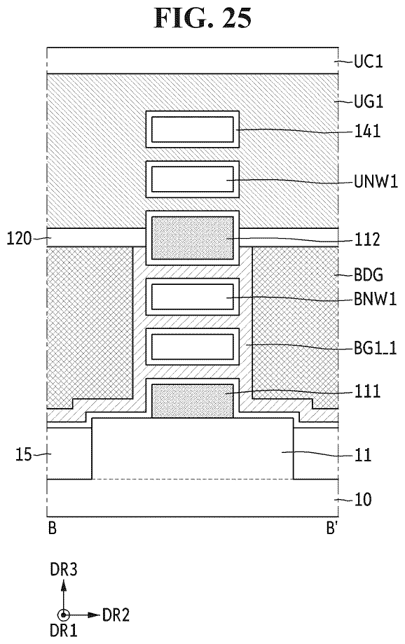

Referring to FIGS. 24 and 25, the first gate insulating layer 141 may be formed on the exposed surface of each of the first active pattern 11, the field insulating layer 15, the bottom isolation layer 111, the first plurality of bottom nanosheets BNW1, the upper isolation layer 112, and the first plurality of upper nanosheets UNW1 inside the first gate trench GT1 (see FIG. 22). Additionally, the second gate insulating layer 142 may be formed on the exposed surface of each of the first active pattern 11, the field insulating layer 15, the bottom isolation layer 111, the second plurality of bottom nanosheets BNW2, the upper isolation layer 112, and the second plurality of upper nanosheets UNW2 inside the second gate trench GT2 (see FIG. 22). Further, the third gate insulating layer 143 may be formed on the exposed surface of each of the first active pattern 11, the field insulating layer 15, the bottom isolation layer 111, the third plurality of bottom nanosheets BNW3, the upper isolation layer 112, and the third plurality of upper nanosheets UNW3 inside the third gate trench GT3 (see FIG. 22).

Subsequently, the first conductive layer BG1_1 may be formed on the upper surface of each of the active pattern 11 and the field insulating layer 15 inside each of the first to third gate trenches GT1, GT2, GT3 (see FIG. 22). For example, the first conductive layer BG1_1 may at least partially surround each of the bottom isolation layer 111, the first to third plurality of bottom nanosheets BNW1, BNW2, BNW3, and a portion of the upper isolation layer 112. Subsequently, the bottom dummy gate BDG may be formed to cover or overlap the first conductive layer BG1_1 inside each of the first to third gate trenches GT1, GT2, GT3 (see FIG. 22). For example, the upper surface of each of the first conductive layer BG1_1 and the bottom dummy gate BDG may be formed on the sidewall of the upper isolation layer 112 in the second horizontal direction DR2. For example, the bottom dummy gate BDG may include polysilicon.

Subsequently, the gate isolation layer 120 may be formed on the upper surface of each of the first conductive layer BG1_1 and the bottom dummy gate BDG inside each of the first to third gate trenches GT1, GT2, GT3 (see FIG. 22). Subsequently, each of the first to third upper gate electrodes UG1, UG2, UG3 may be formed on the upper surface of the gate isolation layer 120 inside each of the first to third gate trenches GT1, GT2, GT3 (see FIG. 22). For example, the first upper gate electrode UG1 may at least partially surround a portion of the upper isolation layer 112 and the first plurality of upper nanosheets UNW1, the second upper gate electrode UG2 may at least partially surround a portion of the upper isolation layer 112 and the second plurality of upper nanosheets UNW2, and the third upper gate electrode UG3 may at least partially surround a portion of the upper isolation layer 112 and the third plurality of upper nanosheets UNW3.

Subsequently, the first upper capping pattern UC1 may be formed on the upper surface of each of the first upper gate electrode UG1, the first gate spacer 131, and the first gate insulating layer 141. The second upper capping pattern UC2 may be formed on the upper surface of each of the second upper gate electrode UG2, the second gate spacer 132, and the second gate insulating layer 142. The third upper capping pattern UC3 may be formed on the upper surface of each of the third upper gate electrode UG3, the third gate spacer 133, and the third gate insulating layer 143.

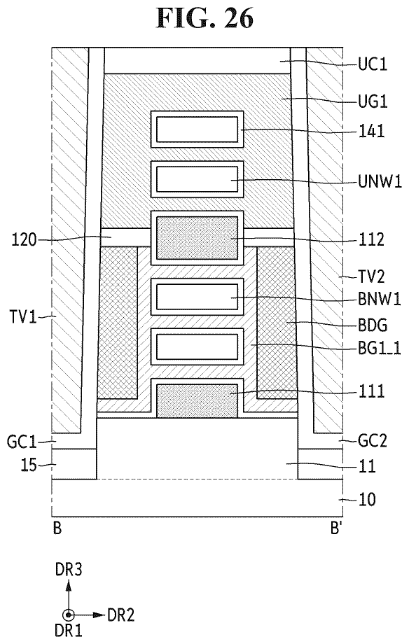

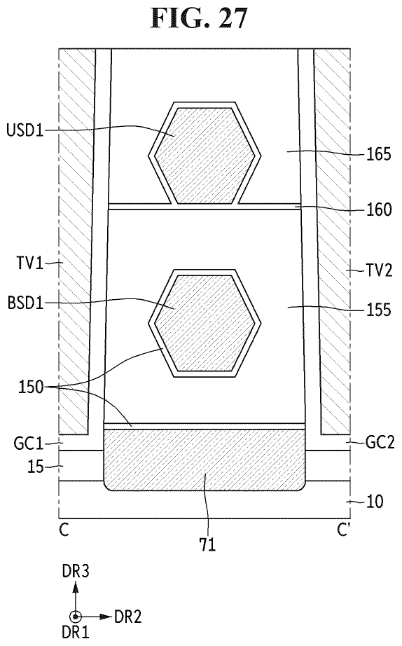

Referring to FIGS. 26 and 27, the first and second gate cuts GC1, GC2 may be formed to penetrate or extend into each of the first to third upper capping patterns UC1, UC2, UC3, the first to third upper gate electrodes UG1, UG2, UG3, the gate isolation layer 120, the bottom dummy gate BDG, the first conductive layer BG1_1, and the first to third gate insulating layers 141, 142, 143 in the vertical direction DR3. For example, each of the first and second gate cuts GC1, GC2 may extend into the inside of the field insulating layer 15. For example, each of the first and second gate cuts GC1, GC2 may extend in the first horizontal direction DR1. For example, the second gate cut GC2 may be spaced apart from the first gate cut GC1 in the second horizontal direction DR2.

Subsequently, the first through via TV1 may be formed inside the first gate cut GC1, and the second through via TV2 may be formed inside the second gate cut GC2. For example, each of the first and second through vias TV1, TV2 may extend in the first horizontal direction DR1. For example, the upper surface of each of the first and second through vias TV1, TV2 may be formed on the same plane as the upper surface of each of the first and second gate cuts GC1, GC2. For example, the bottom surface of each of the first and second through vias TV1, TV2 may be formed higher than the bottom surface of each of the first and second gate cuts GC1, GC2.

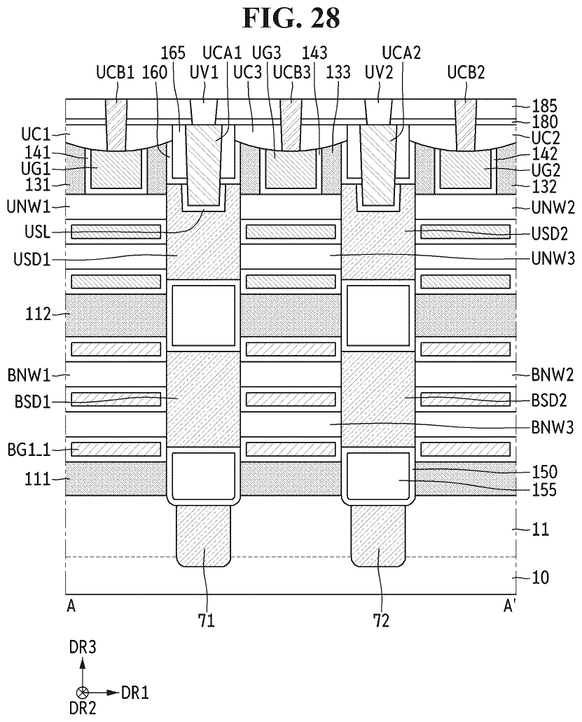

Referring to FIGS. 28 to 30, the first upper source/drain contact UCA1 may be formed to penetrate or extend into the second upper interlayer insulating layer 165 and the second etch stop layer 160 in the vertical direction DR3 and connect to the first upper source/drain region USD1. For example, at least a portion of the bottom surface of the first upper source/drain contact UCA1 may be in contact with the second gate cut GC2. For example, the sidewall of the first upper source/drain contact UCA1 in the second horizontal direction DR2 may be in contact with the second through via TV2. The second upper source/drain contact UCA2 may be formed to penetrate or extend into the second upper interlayer insulating layer 165 and the second etch stop layer 160 in the vertical direction DR3 and connect to the second upper source/drain region USD2. Additionally, the upper silicide layer USL may be formed between each of the first and second upper source/drain regions USD1, USD2 and each of the first and second upper source/drain contacts UCA1, UCA2.

Subsequently, the third etch stop layer 180 and the third upper interlayer insulating layer 185 may be formed sequentially on the upper surface of each of the first to third upper capping patterns UC1, UC2, UC3, the first and second gate cuts GC1, GC2, the first and second through vias TV1, TV2, the first and second upper source/drain contacts UCA1, UCA2, and the second upper interlayer insulating layer 165. Subsequently, the first upper gate contact UCB1 may be formed to penetrate or extend into the third upper interlayer insulating layer 185, the third etch stop layer 180, and the first upper capping pattern UC1 in the vertical direction DR3 and connect to the first upper gate electrode UG1. The second upper gate contact UCB2 may be formed to penetrate or extend into the third upper interlayer insulating layer 185, the third etch stop layer 180, and the second upper capping pattern UC2 in the vertical direction DR3 and connect to the second upper gate electrode UG2. The third upper gate contact UCB3 may be formed to penetrate or extend into the third upper interlayer insulating layer 185, the third etch stop layer 180, and the third upper capping pattern UC3 in the vertical direction DR3 and connect to the third upper gate electrode UG3.

Additionally, the first upper via UV1 may be formed to penetrate or extend into the third upper interlayer insulating layer 185 and the third etch stop layer 180 in the vertical direction DR3 and connect to the first upper source/drain contact UCA1. The second upper via UV2 may be formed to penetrate or extend into the third upper interlayer insulating layer 185 and the third etch stop layer 180 in the vertical direction DR3 and connect to the second upper source/drain contact UCA2.

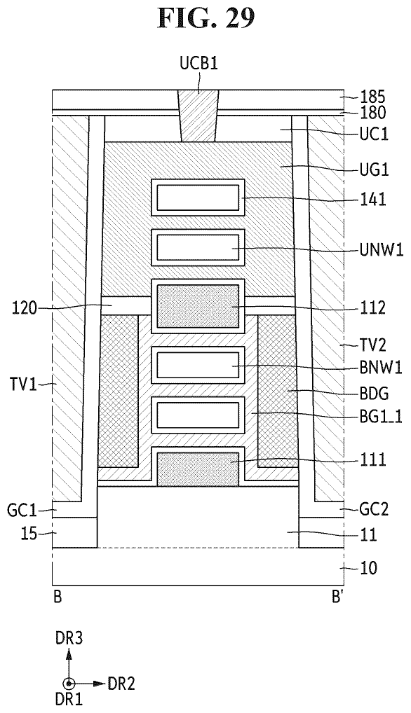

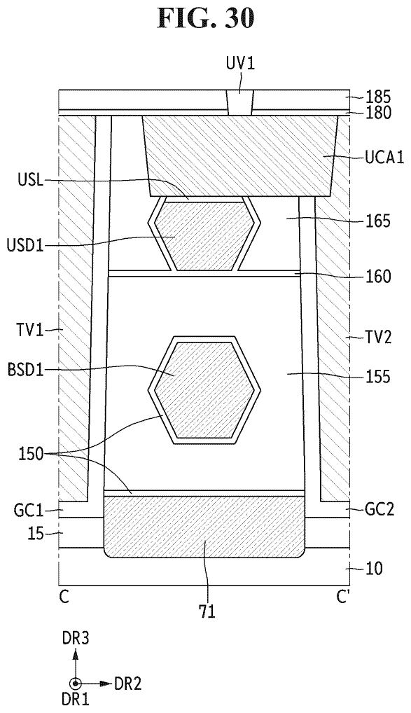

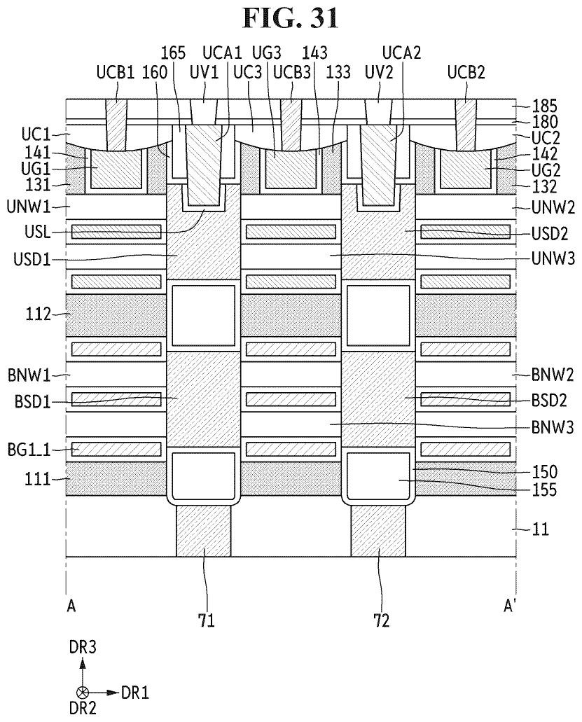

Referring to FIGS. 31 to 33, the substrate 10 (see FIGS. 28 to 30) may be etched by performing a planarization process. While the substrate 10 (see FIGS. 28 to 30) is being etched, a portion of each of the first and second sacrificial patterns 71, 72 may also be etched. Through this etching process, the bottom surface of the field insulating layer 15 (see FIGS. 29 and 30) may be exposed. Subsequently, the field insulating layer 15 (see FIG. 29 and FIG. 30) may be etched.

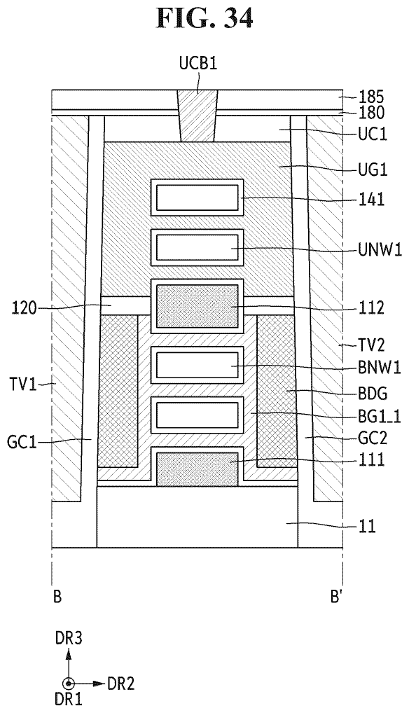

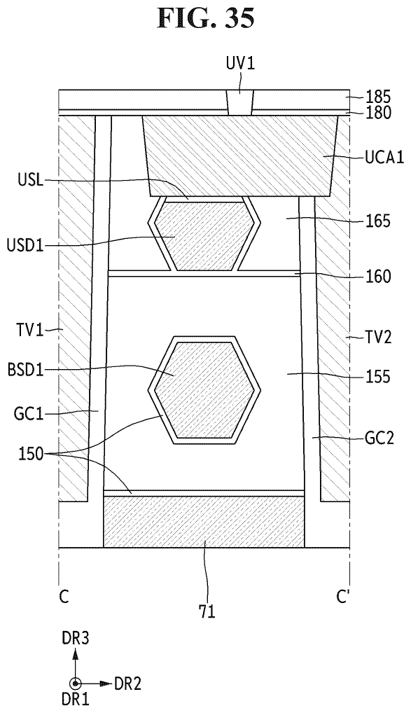

Referring to FIGS. 34 and 35, the portion where the field insulating layer 15 (see FIGS. 29 and 30) is etched may be at least partially filled with the same material as each of the first and second gate cuts GC1, GC2. Through the planarization process, the bottom surface of each of the first and second gate cuts GC1, GC2 may be formed on the same plane as the bottom surface of each of the active pattern 11 and the first sacrificial pattern 71.

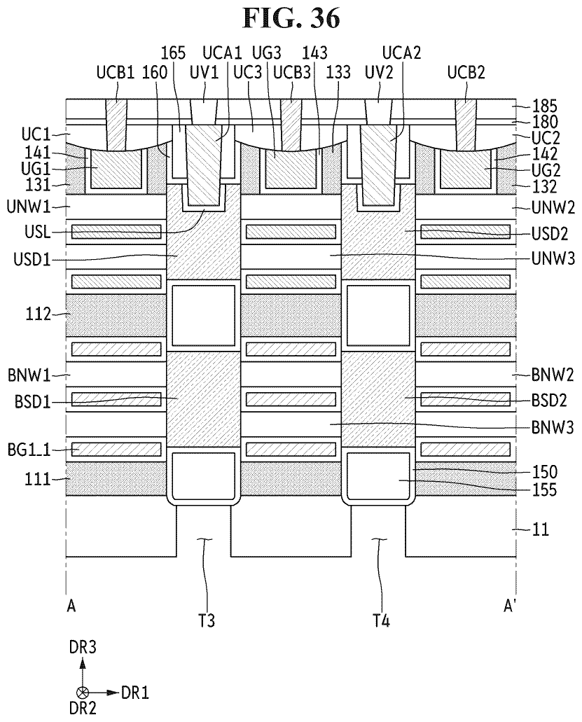

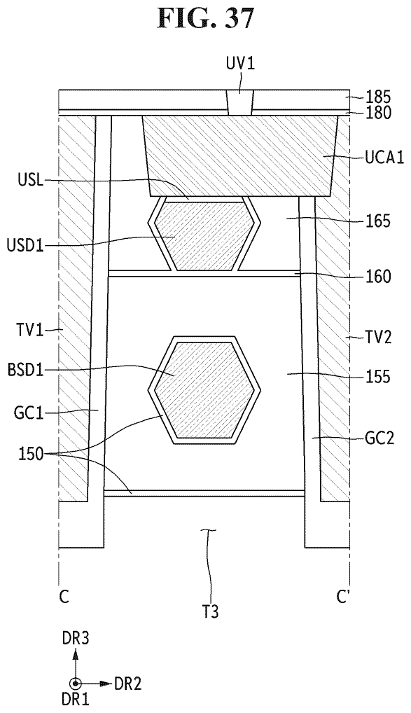

Referring to FIGS. 36 and 37, the first sacrificial pattern 71 (see FIG. 31) may be etched to form the first trench T3, and the second sacrificial pattern 72 (see FIG. 31) may be etched to form the second trench T4. For example, through each of the first and second trenches T3, T4, the first etch stop layer 150 may be exposed between the active patterns 11.

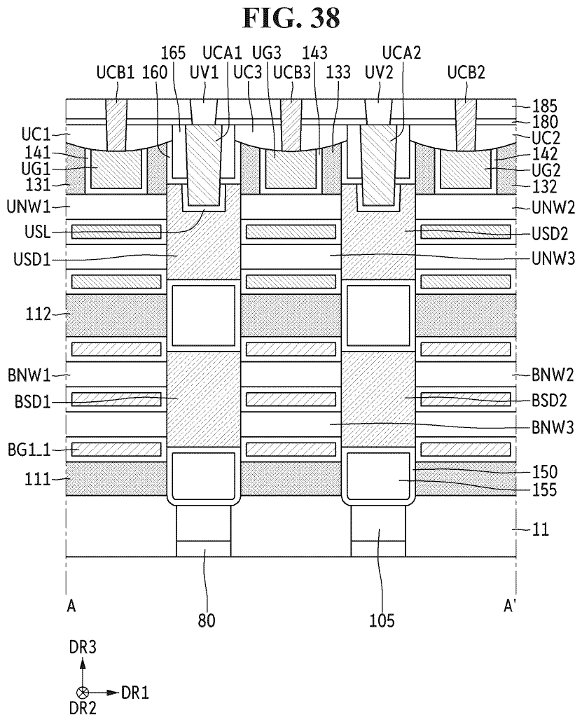

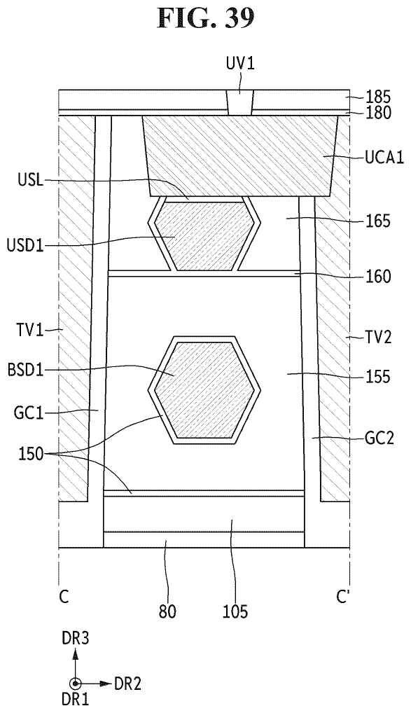

Referring to FIGS. 38 and 39, the second lower interlayer insulating layer 105 and the insulating layer 80 may be formed sequentially inside each of the first and second trenches T3, T4 (see FIGS. 36 and 37). The insulating layer 80 may be formed at the lower portion of the second lower interlayer insulating layer 105 inside each of the first and second trenches T3, T4 (see FIGS. 36 and 37). For example, the bottom surface of the insulating layer 80 may be formed on the same plane as the bottom surface of the active pattern 11. For example, the insulating layer 80 may include at least one of silicon nitride (SiN), silicon oxynitride (SiON), silicon oxide (SiO₂), silicon carbonitride (SiCN), silicon oxycarbonitride (SiOCN), and/or combinations thereof.

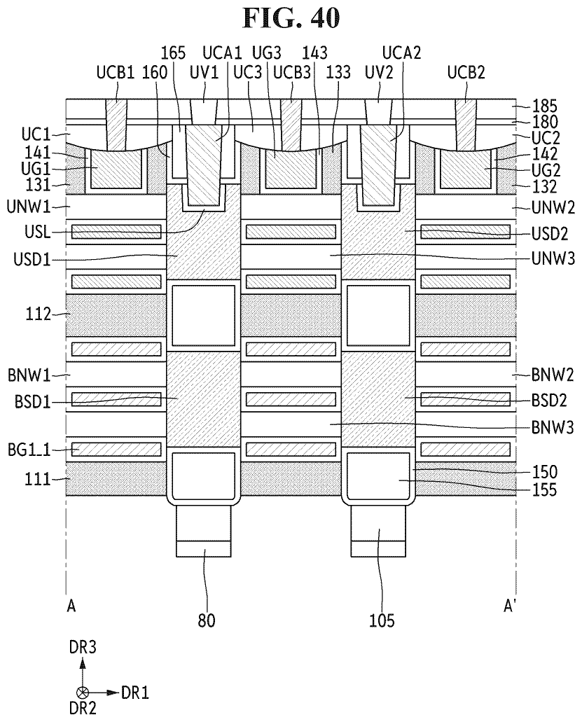

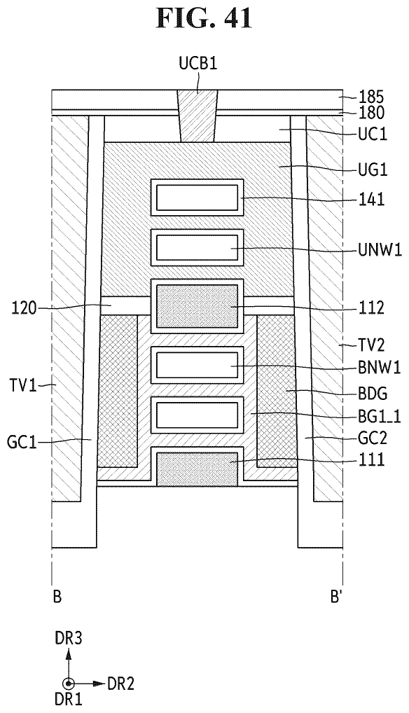

Referring to FIGS. 40 and 41, the active pattern 11 (see FIG. 38) may be etched. For example, after the active pattern 11 (see FIG. 38) is etched, each of the bottom isolation layer 111 and first to third gate insulating layers 141, 142, 143 may be exposed between the first gate cut GC1 and the second gate cut GC2.

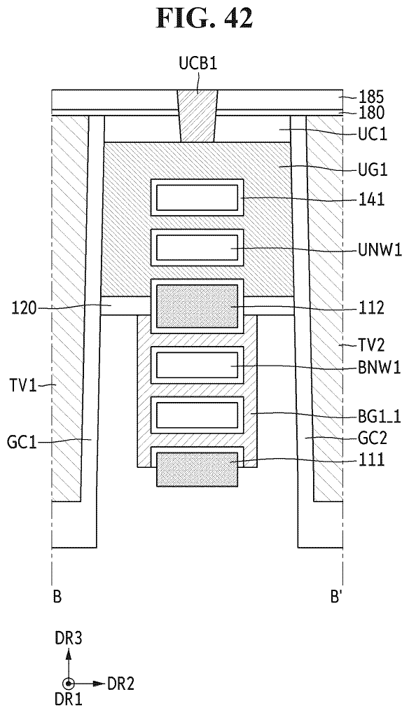

Referring to FIG. 42, a portion of each of the first to third gate insulating layers 141, 142, 143, a portion of the first conductive layer BG1_1, and the bottom dummy gate BDG may be etched, respectively. Through such an etching process, a portion of the sidewall and the bottom surface of the bottom isolation layer 111 in the second horizontal direction DR2 may be exposed.

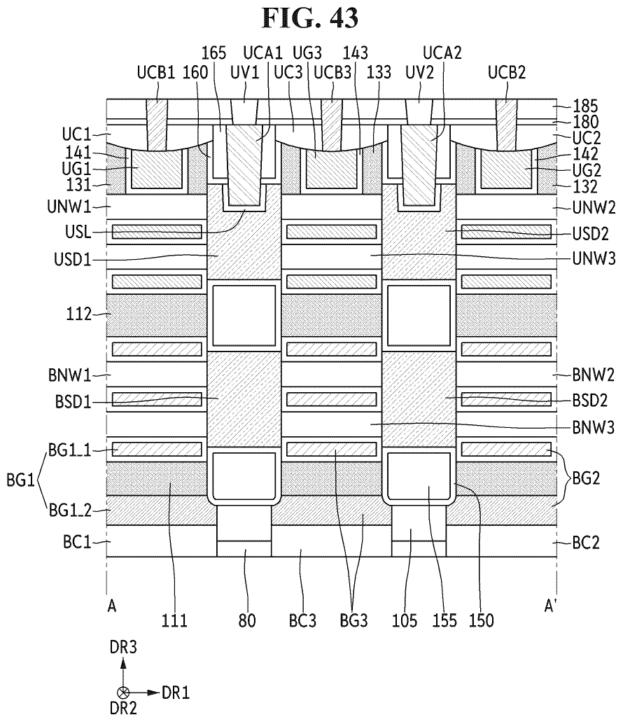

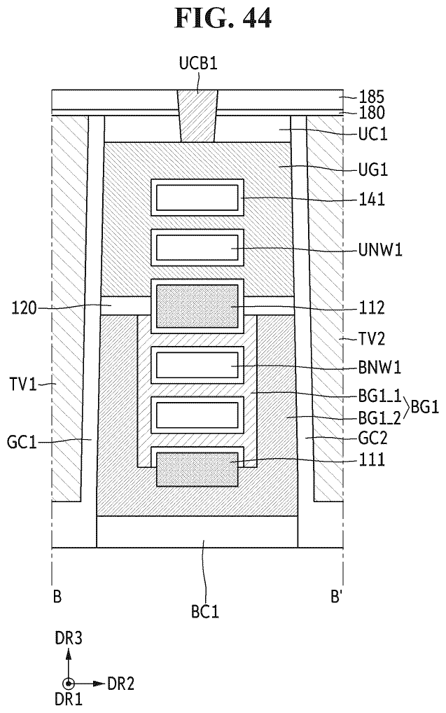

Referring to FIG. 43 and FIG. 44, the second conductive layer BG1_2 may be formed to at least partially surround each of the first conductive layer BG1_1 and the bottom isolation layer 111 between the first gate cut GC1 and the second gate cut GC2. Accordingly, each of the first to third bottom gate electrodes BG1, BG2, BG3 may be formed at the lower portion of each of the first to third upper gate electrodes UG1, UG2, UG3 between the first gate cut GC1 and the second gate cut GC2. Subsequently, each of the first to third bottom capping patterns BC1, BC2, BC3 may be formed on the bottom surface of each of the first to third bottom gate electrodes BG1, BG2, BG3. For example, the first bottom capping pattern BC1 may be in contact with the bottom surface of the first bottom gate electrode BG1, the second bottom capping pattern BC2 may be in contact with the bottom surface of the second bottom gate electrode BG2, and the third bottom capping pattern BC3 may be in contact with the bottom surface of the third bottom gate electrode BG3.

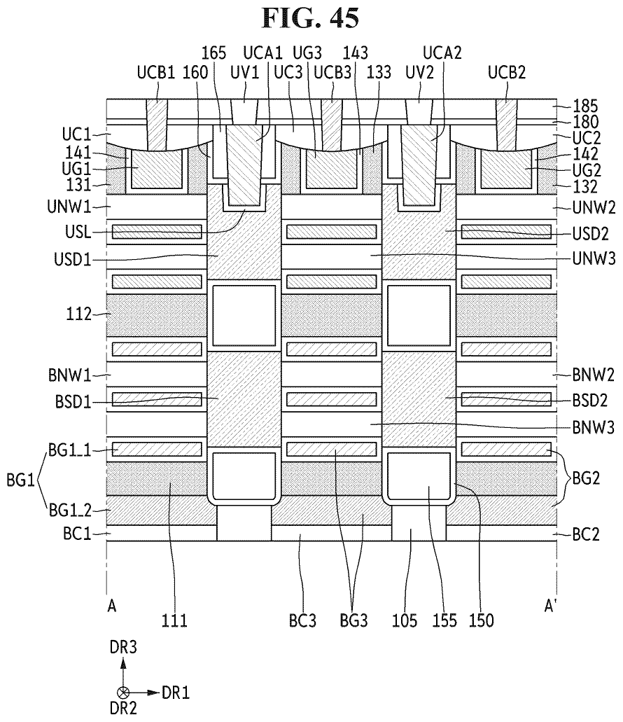

Referring to FIGS. 45 to 47, the insulating layer 80 may be etched to expose the bottom surface of the second lower interlayer insulating layer 105 by performing a planarization process. While the insulating layer 80 is etched, a portion of each of the first to third bottom capping patterns BC1, BC2, BC3 may also be etched.

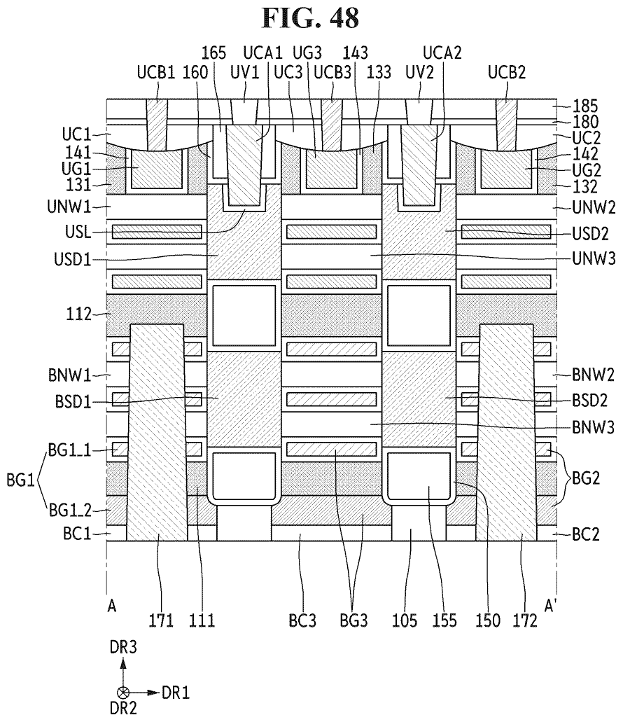

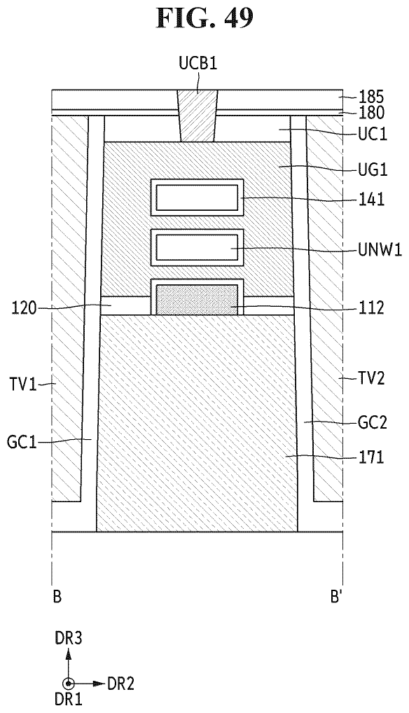

Referring to FIGS. 48 and 49, the first active cut 171 penetrating or extending into each of the first bottom capping pattern BC1, the first bottom gate electrode BG1, and the first plurality of bottom nanosheets BNW1 in the vertical direction DR3 may be formed between the first gate cut GC1 and the second gate cut GC2. Further, the second active cut 172 penetrating or extending into each of the second bottom capping pattern BC2, the second bottom gate electrode BG2, and the second plurality of bottom nanosheets BNW2 in the vertical direction DR3 may be formed between the first gate cut GC1 and the second gate cut GC2. For example, each of the first and second active cuts 171, 172 may extend into the inside of the upper isolation layer 112.

For example, both sidewalls of each of the first and second active cuts 171, 172 in the second horizontal direction DR2 may be in contact with each of the first and second gate cuts GC1, GC2. For example, the first active cut 171 may be disposed at the lower portion of each of the first upper gate electrode UG1 and the first plurality of upper nanosheets UNW1. The second active cut 172 may be disposed at the lower portion of each of the second upper gate electrode UG2 and the second plurality of upper nanosheets UNW2. For example, the upper surface of each of the first and second active cuts 171, 172 may be in contact with each of the gate isolation layer 120 and the upper isolation layer 112.

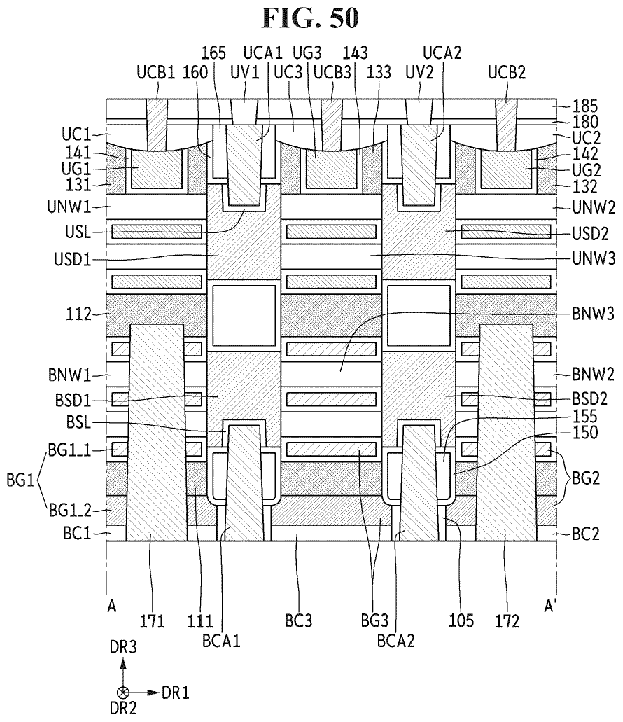

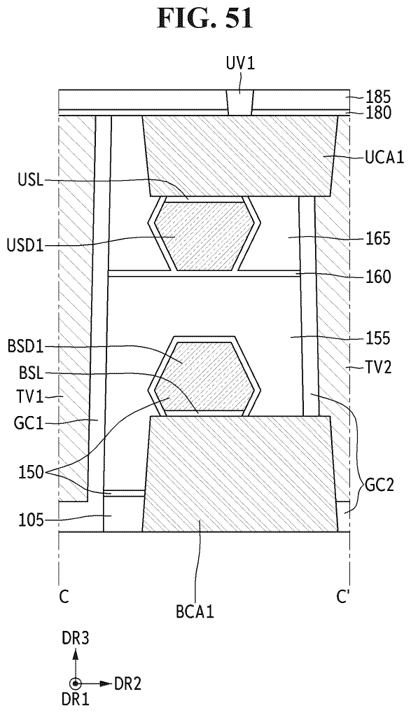

Referring to FIGS. 50 and 51, the first bottom source/drain contact BCA1 may be formed, which penetrates or extends into the second lower interlayer insulating layer 105, the first etch stop layer 150, and the first upper interlayer insulating layer 155 in the vertical direction DR3 and extends into the inside of the first bottom source/drain region BSD1. For example, at least a portion of the upper surface of the first bottom source/drain contact BCA1 may be in contact with the second gate cut GC2. For example, the one sidewall of the first bottom source/drain contact BCA1 in the second horizontal direction DR2 may be in contact with the second through via TV2. Further, the second bottom source/drain contact BCA2 may be formed, which penetrates or extends into the second lower interlayer insulating layer 105, the first etch stop layer 150, and the first upper interlayer insulating layer 155 in the vertical direction DR3 and extends into the inside of the second bottom source/drain region BSD2. For example, the bottom surface of each of the first and second bottom source/drain contacts BCA1, BCA2 may be formed on the same plane as the bottom surface of each of the first to third bottom capping patterns BC1, BC2, BC3, and the first and second active cuts 171, 172.

Referring to FIGS. 2 to 4, the first lower interlayer insulating layer 100 may be formed on the bottom surface of each of the first and second bottom source/drain contacts BCA1, BCA2, the first to third bottom capping patterns BC1, BC2, BC3, the first and second active cuts 171, 172, the first and second gate cuts GC1, GC2, and the second lower interlayer insulating layer 105. Subsequently, the first bottom gate contact BCB1 may be formed, which penetrates or extends into the first lower interlayer insulating layer 100 and the second bottom capping pattern BC2 in the vertical direction DR3 and connects to the second bottom gate electrode BG2. Further, the first bottom via BV1 may be formed, which penetrates or extends into the first lower interlayer insulating layer 100 in the vertical direction DR3 and connects to the first bottom source/drain contact BCA1, and the second bottom via BV2 may be formed, which penetrates or extends into the first lower interlayer insulating layer 100 in the vertical direction DR3 and connects to the second bottom source/drain contact BCA2. Through such a fabrication process, the semiconductor device shown in FIGS. 2 to 4 may be fabricated.

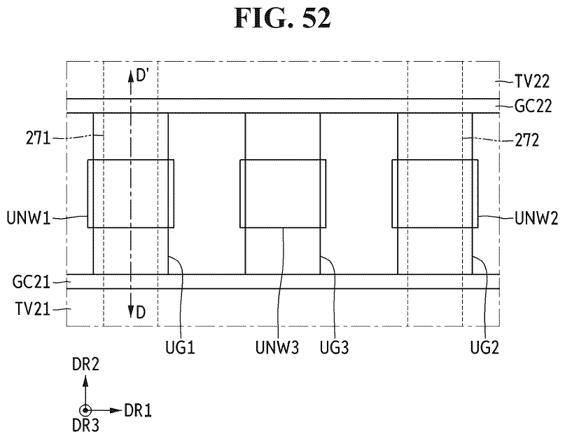

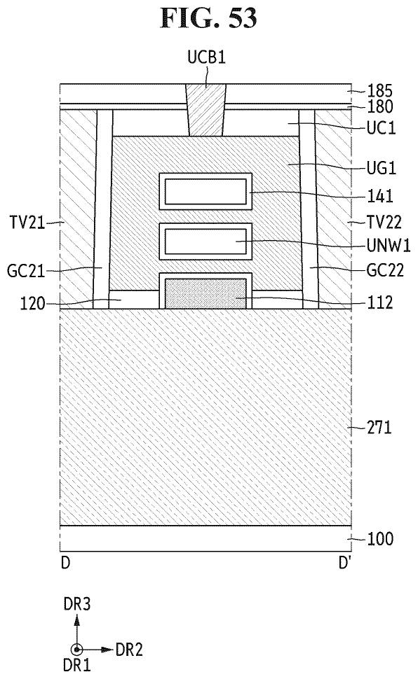

Hereinafter, the semiconductor device according to some other embodiments of the present disclosure will be described with reference to FIG. 52 and FIG. 53. The description will focus on the differences from the semiconductor devices shown in FIGS. 1 to 4.

FIG. 52 is a layout diagram for explaining the semiconductor device according to some other embodiments of the present disclosure. FIG. 53 is a cross-sectional view taken along lines D-D′ of FIG. 52.

Referring to FIGS. 52 and 53, in the semiconductor device according to some other embodiments of the present disclosure, each of the first active cut 271 and the second active cut 272 may extend in the second horizontal direction DR2 at the lower portion of each of the first and second gate cuts GC21, GC22.

For example, the upper surface of each of the first and second active cuts 271, 272 may be in contact with the bottom surface of each of the first and second gate cuts GC21, GC22. For example, the upper surface of each of the first and second active cuts 271, 272 may be in contact with the bottom surface of each of the first and second through vias TV21, TV22.

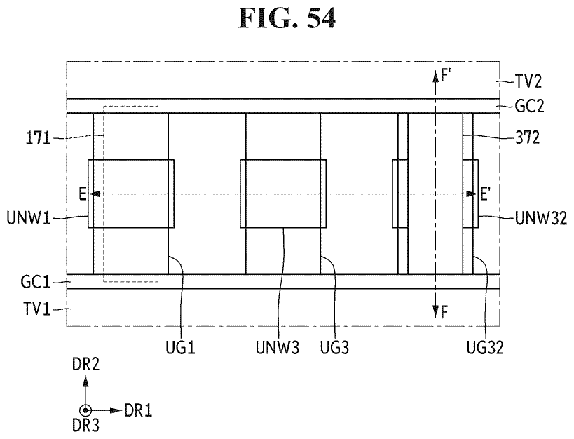

Hereinafter, the semiconductor device according to some other embodiments of the present disclosure will be described with reference to FIGS. 54 to 56. The description will focus on the differences from the semiconductor devices shown in FIGS. 1 to 4.

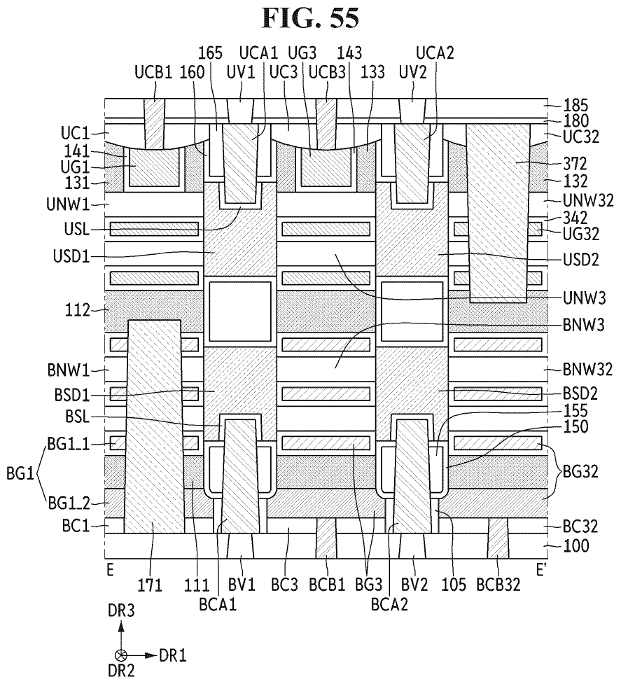

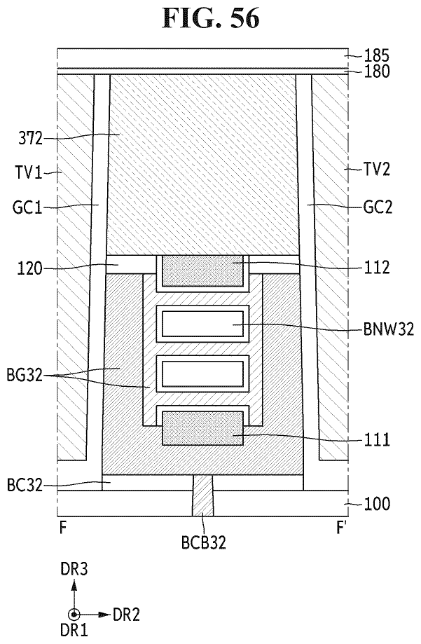

FIG. 54 is a layout diagram for explaining the semiconductor device according to another several embodiments of the present disclosure. FIG. 55 is a cross-sectional view taken along the line E-E′ of FIG. 54. FIG. 56 is a cross-sectional view taken along the line F-F′ of FIG. 54.

Referring to FIGS. 54 and 56, in the semiconductor device according to some other embodiments of the present disclosure, the second active cut 372 may be disposed on the upper surface of the second bottom gate electrode BG32.

For example, the second active cut 372 may penetrate or extend into each of the second upper gate electrode UG32, the second plurality of upper nanosheets UNW32, and the second upper capping pattern UC32 in the vertical direction DR3 between the first gate cut GC1 and the second gate cut GC2. For example, the second active cut 372 may be disposed between the second gate spacers 132. For example, the upper surface of the second active cut 372 may be formed on the same plane as the upper surface of the second upper capping pattern UC32. For example, the second active cut 372 may extend into the inside of the upper isolation layer 112. For example, the bottom surface of the second active cut 372 may be in contact with the gate isolation layer 120 and the upper isolation layer 112.

For example, both sidewalls of the second active cut 372 in the first horizontal direction DR1 may be in contact with each of the second gate spacer 132, the second gate insulating layer 342, the second upper gate electrode UG32, the second plurality of upper nanosheets UNW32, and the second upper capping pattern UC32. For example, both sidewalls of the second active cut 372 in the second horizontal direction DR2 may be in contact with each of the first and second gate cuts GC1, GC2. For example, the second active cut 372 may be spaced apart from the upper surface of the second bottom gate electrode BG32 in the vertical direction DR3. For example, the second active cut 372 may overlap with each of the second bottom gate electrode BG32 and the second plurality of bottom nanosheets BNW32 in the vertical direction DR3. For example, the second bottom gate contact BCB32 may penetrate or extend into the first lower interlayer insulating layer 100 and the second bottom capping pattern BC32 in the vertical direction DR3 to be connected to the second bottom gate electrode BG32.

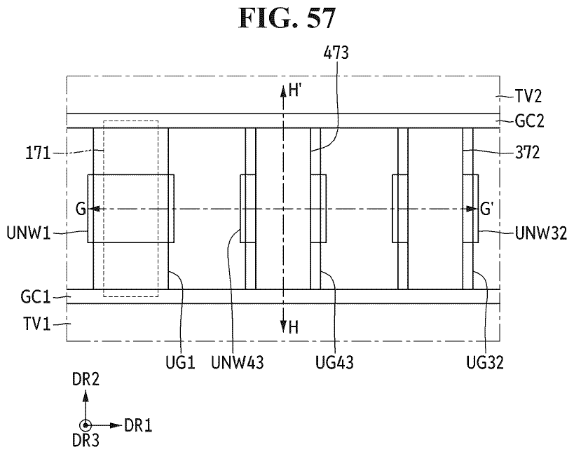

Hereinafter, the semiconductor device according to some other embodiments of the present disclosure will be described with reference to FIGS. 57 to 59. The description will focus on the differences from the semiconductor device shown in FIGS. 54 to 56.

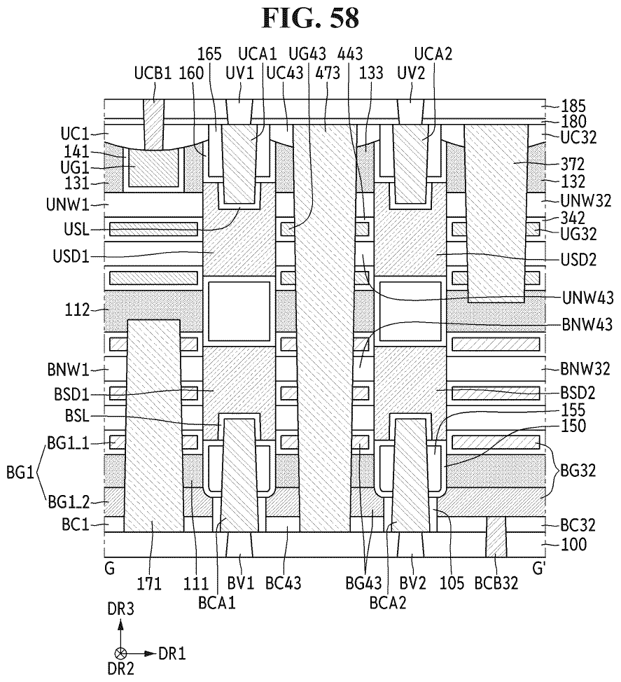

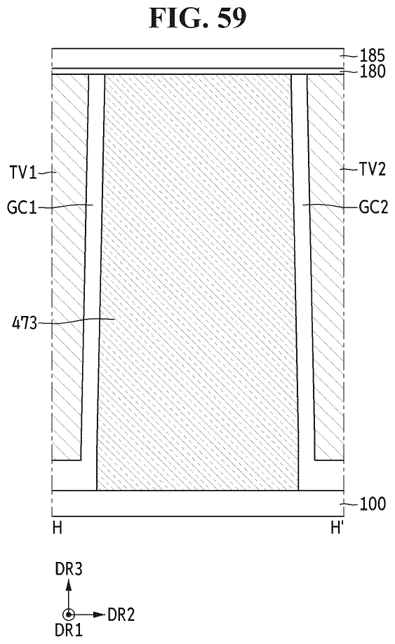

FIG. 57 is a layout diagram for explaining the semiconductor device according to another several embodiments of the present disclosure. FIG. 58 is a cross-sectional view taken along the line G-G′ of FIG. 57. FIG. 59 is a cross-sectional view taken along the line H-H′ of FIG. 57.

Referring to FIGS. 57 to 59, in the semiconductor device according to some other embodiments of the present disclosure, the third active cut 473 may be disposed between the first active cut 171 and the second active cut 372.

For example, between the first gate cut GC1 and the second gate cut GC2, the third active cut 473 may penetrate or extend into the third bottom capping pattern BC43, the third bottom gate electrode BG43, the bottom isolation layer 111, the third plurality of bottom nanosheets BNW43, the upper isolation layer 112, the third upper gate electrode UG43, the third plurality of upper nanosheets UNW43, the third gate insulating layer 443, and the third upper capping pattern UC43 in the vertical direction DR3. For example, the third active cut 473 may be disposed between the third gate spacers 133. For example, the upper surface of the third active cut 473 may be formed on the same plane as each of the upper surface of the third upper capping pattern UC43 and the upper surface of the second active cut 372. For example, the bottom surface of the third active cut 473 may be formed on the same plane as each of the bottom surface of the third bottom capping pattern BC43 and the bottom surface of the first active cut 171. For example, the bottom surface of the third active cut 473 may be in contact with the first lower interlayer insulating layer 100.

For example, both sidewalls of the third active cut 473 in the first horizontal direction DR1 may be in contact with the third gate spacer 133, the third bottom capping pattern BC43, the third bottom gate electrode BG43, the bottom isolation layer 111, the third plurality of bottom nanosheets BNW43, upper isolation layer 112, the third upper gate electrode UG43, the third plurality of upper nanosheets UNW43, the third gate insulating layer 443, and the third upper capping pattern UC43, respectively. For example, both sidewalls of the third active cut 473 in the second horizontal direction DR2 may be in contact with each of the first and second gate cuts GC1, GC2.

While embodiments according to the present disclosure have been described above with reference to the accompanying drawings, it will be understood that the present disclosure is not limited to the above embodiments and may be fabricated in a variety of different forms, and those skilled in the art to which the present disclosure belongs, with ordinary knowledge in the field, may recognize that it may be implemented in other specific forms without changing the technical idea or essential features of the present disclosure. Therefore, it should be understood that the above-described embodiments are examples in all respects and not restrictive.

What is claimed is:

1. A semiconductor device comprising:
a lower interlayer insulating layer that extends in each of a first horizontal direction and a second horizontal direction that intersects the first horizontal direction,
a first plurality of bottom nanosheets stacked and spaced apart from each other in a vertical direction that is perpendicular to the first horizontal direction and the second horizontal direction, wherein the first plurality of bottom nanosheets are on the lower interlayer insulating layer;
a first plurality of upper nanosheets that are spaced apart from the first plurality of bottom nanosheets in the vertical direction, wherein the first plurality of upper nanosheets are stacked and spaced apart from each other in the vertical direction;
an upper isolation layer between an uppermost nanosheet of the first plurality of bottom nanosheets and a lowermost nanosheet of the first plurality of upper nanosheets;
a first bottom gate electrode that extends in the second horizontal direction and is on the lower interlayer insulating layer, wherein the first bottom gate electrode at least partially surrounds the first plurality of bottom nanosheets;
a first upper gate electrode that extends in the second horizontal direction and is on an upper surface of the first bottom gate electrode, wherein the first upper gate electrode is spaced apart from the first bottom gate electrode in the vertical direction, and wherein the first upper gate electrode at least partially surrounds the first plurality of upper nanosheets; and
a first active cut that extends into each of the first bottom gate electrode and the first plurality of bottom nanosheets in the vertical direction and is on an upper surface of the lower interlayer insulating layer, wherein the first active cut is spaced apart from the first upper gate electrode in the vertical direction, and wherein the first active cut at least partially overlaps each of the first upper gate electrode and the first plurality of upper nanosheets in the vertical direction.

2. The semiconductor device of claim 1, wherein an upper surface of the first active cut is in contact with the upper isolation layer.

3. The semiconductor device of claim 1, wherein a width of an upper surface of the first active cut in the first horizontal direction is less than a width of a bottom surface of the first active cut in the first horizontal direction.

4. The semiconductor device of claim 1, wherein both sidewalls of the first active cut are in contact with each of the first bottom gate electrode and the first plurality of bottom nanosheets.

5. The semiconductor device of claim 1, further comprising:
a first bottom capping pattern between the lower interlayer insulating layer and the first bottom gate electrode, wherein the first bottom capping pattern is in contact with a bottom surface of the first bottom gate electrode, and wherein the first bottom capping pattern being is in contact with both sidewalls of the first active cut.

6. The semiconductor device of claim 5, wherein a bottom surface of the first active cut is coplanar with a bottom surface of the first bottom capping pattern.

7. The semiconductor device of claim 1, further comprising:
a gate isolation layer that is between an upper surface of the first active cut and a bottom surface of the first upper gate electrode and is on both sidewalls of the upper isolation layer.

8. The semiconductor device of claim 1, further comprising:
a bottom source/drain region in contact with a first sidewall of the first plurality of bottom nanosheets; and
an upper source/drain region in contact with a first sidewall of the first plurality of upper nanosheets, wherein the upper source/drain region is spaced apart from the bottom source/drain region in the vertical direction,
wherein a distance between an upper surface of the first active cut and an upper surface of the lower interlayer insulating layer in the vertical direction is greater than a distance between an upper surface of the bottom source/drain region and the upper surface of the lower interlayer insulating layer in the vertical direction, and
wherein a distance between a bottom surface of the first active cut and the upper surface of the lower interlayer insulating layer in the vertical direction is less than a distance between a bottom surface of the upper source/drain region and the upper surface of the lower interlayer insulating layer in the vertical direction.

9. The semiconductor device of claim 1, further comprising:
a gate cut that extends in the first horizontal direction and is on a sidewall of the first upper gate electrode, wherein the gate cut is in contact with a sidewall of the first active cut.

10. The semiconductor device of claim 1, further comprising:
a gate cut that extends in the first horizontal direction and is on a sidewall of the first upper gate electrode, wherein the gate cut is in contact with an upper surface of the first active cut.

11. The semiconductor device of claim 1, further comprising:
a second plurality of bottom nanosheets that are stacked and spaced apart from each other in the vertical direction and are on the lower interlayer insulating layer, wherein the second plurality of bottom nanosheets are spaced apart from the first plurality of bottom nanosheets in the first horizontal direction;
a second plurality of upper nanosheets that are spaced apart from the second plurality of bottom nanosheets in the vertical direction, wherein the second plurality of upper nanosheets are stacked and spaced apart from each other in the vertical direction, and wherein the second plurality of upper nanosheets are spaced apart from the first plurality of upper nanosheets in the first horizontal direction;
a second bottom gate electrode that extends in the second horizontal direction and is on the lower interlayer insulating layer, wherein the second bottom gate electrode is spaced apart from the first bottom gate electrode in the first horizontal direction, and wherein the second bottom gate electrode at least partially surrounds the second plurality of bottom nanosheets;
a second upper gate electrode that extends in the second horizontal direction and is on an upper surface of the second bottom gate electrode, wherein the second upper gate electrode is spaced apart from the second bottom gate electrode in the vertical direction, and wherein the second upper gate electrode at least partially surrounds the second plurality of upper nanosheets; and
a second active cut that extends into each of the second upper gate electrode and the second plurality of upper nanosheets in the vertical direction and is on the upper surface of the second bottom gate electrode, wherein the second active cut is spaced apart from the upper surface of the second bottom gate electrode in the vertical direction, and wherein the second active cut at least partially overlaps each of the second bottom gate electrode and the second plurality of bottom nanosheets in the vertical direction.

12. The semiconductor device of claim 11, further comprising:
a second bottom capping pattern between the lower interlayer insulating layer and the second bottom gate electrode, wherein the second bottom capping pattern is in contact with a bottom surface of the second bottom gate electrode; and
a bottom gate contact that extends into the second bottom capping pattern in the vertical direction, wherein the bottom gate contact is electrically connected to the second bottom gate electrode.

13. A semiconductor device comprising:
a lower interlayer insulating layer;
a first plurality of bottom nanosheets that are stacked and spaced apart from each other in a vertical direction that is perpendicular to an upper surface of the lower interlayer insulating layer and are on the lower interlayer insulating layer;
a second plurality of bottom nanosheets that are stacked and spaced apart from each other in the vertical direction and are on the lower interlayer insulating layer, wherein the second plurality of bottom nanosheets are spaced apart from the first plurality of bottom nanosheets in a first horizontal direction that is perpendicular to the vertical direction;
a first plurality of upper nanosheets that are spaced apart from the first plurality of bottom nanosheets in the vertical direction, wherein the first plurality of upper nanosheets are stacked and spaced apart from each other in the vertical direction;
a second plurality of upper nanosheets that are spaced apart from the second plurality of bottom nanosheets in the vertical direction, wherein the second plurality of upper nanosheets are stacked and spaced apart from each other in the vertical direction, and wherein the second plurality of upper nanosheets are spaced apart from the first plurality of upper nanosheets in the first horizontal direction;
a first upper gate electrode that extends in a second horizontal direction that intersects the first horizontal direction, wherein the first upper gate electrode at least partially surrounds the first plurality of upper nanosheets;
a second upper gate electrode that extends in the second horizontal direction, wherein the second upper gate electrode is spaced apart from the first upper gate electrode in the first horizontal direction, and wherein the second upper gate electrode at least partially surrounds the second plurality of upper nanosheets;
a first active cut that extends into the first plurality of bottom nanosheets in the vertical direction and is on the upper surface of the lower interlayer insulating layer, wherein the first active cut is spaced apart from the first upper gate electrode in the vertical direction, and wherein the first active cut at least partially overlaps each of the first upper gate electrode and the first plurality of upper nanosheets in the vertical direction; and
a gate cut that extends in the first horizontal direction and is on a sidewall of each of the first upper gate electrode and the second upper gate electrode, wherein the gate cut is in contact with the sidewall of each of the first upper gate electrode and the second upper gate electrode.

14. The semiconductor device of claim 13, further comprising:
a first bottom gate electrode that extends in the second horizontal direction and is between the upper surface of the lower interlayer insulating layer and the first upper gate electrode, wherein the first bottom gate electrode is spaced apart from the first upper gate electrode in the vertical direction, wherein the first bottom gate electrode at least partially surrounds the first plurality of bottom nanosheets, and wherein the first bottom gate electrode is in contact with a first sidewall of the first active cut and a second sidewall of the first active cut in the first horizontal direction;
a second bottom gate electrode that extends in the second horizontal direction and is between the upper surface of the lower interlayer insulating layer and the second upper gate electrode, wherein the second bottom gate electrode is spaced apart from the first bottom gate electrode in the first horizontal direction, wherein the second bottom gate electrode is spaced apart from the second upper gate electrode in the vertical direction, and wherein the second bottom gate electrode at least partially surrounds the second plurality of bottom nanosheets; and
an upper isolation layer between an uppermost nanosheet of the first plurality of bottom nanosheets and a lowermost nanosheet of the first plurality of upper nanosheets, wherein the upper isolation layer is between an uppermost nanosheet of the second plurality of bottom nanosheets and a lowermost nanosheet of the second plurality of upper nanosheets.

15. The semiconductor device of claim 13, wherein the gate cut is in contact with the first sidewall of the first active cut.

16. The semiconductor device of claim 13, further comprising:
a second active cut that extends into the second plurality of bottom nanosheets in the vertical direction and is on the upper surface of the lower interlayer insulating layer, wherein the second active cut is spaced apart from the first active cut in the first horizontal direction, wherein the second active cut is spaced apart from the second upper gate electrode in the vertical direction, and wherein the second active cut at least partially overlaps each of the second upper gate electrode and the second plurality of upper nanosheets in the vertical direction.

17. The semiconductor device of claim 13, further comprising:
a bottom source/drain region in contact with a first sidewall of the first plurality of bottom nanosheets;
an upper source/drain region in contact with a first sidewall of the first plurality of upper nanosheets, wherein the upper source/drain region is spaced apart from the bottom source/drain region in the vertical direction;
a bottom source/drain contact on a lower portion of the bottom source/drain region, wherein the bottom source/drain contact is electrically connected to the bottom source/drain region; and
an upper source/drain contact on an upper portion of the upper source/drain region, wherein the upper source/drain contact is electrically connected to the upper source/drain region,
wherein a distance between an upper surface of the first active cut and the upper surface of the lower interlayer insulating layer in the vertical direction is greater than a distance between an upper surface of the bottom source/drain region and the upper surface of the lower interlayer insulating layer in the vertical direction, and
wherein a distance between a bottom surface of the first active cut and the upper surface of the lower interlayer insulating layer in the vertical direction is less than a distance between a bottom surface of the upper source/drain region and the upper surface of the lower interlayer insulating layer in the vertical direction.

18. The semiconductor device of claim 17, further comprising:
a through via that extends in the first horizontal direction and extends into the gate cut, wherein the through via is in contact with each of the bottom source/drain contact and the upper source/drain contact.

19. The semiconductor device of claim 13, further comprising:
a third plurality of bottom nanosheets that are stacked and spaced apart from each other in the vertical direction and are on the lower interlayer insulating layer, wherein the third plurality of bottom nanosheets are between the first plurality of bottom nanosheets and the second plurality of bottom nanosheets, and wherein the third plurality of bottom nanosheets are spaced apart from each of the first plurality of bottom nanosheets and the second plurality of bottom nanosheets in the first horizontal direction;
a third plurality of upper nanosheets that are spaced apart from the third plurality of bottom nanosheets in the vertical direction, wherein the third plurality of upper nanosheets are stacked and spaced apart from each other in the vertical direction, and wherein the third plurality of upper nanosheets are spaced apart from each of the first plurality of upper nanosheets and the second plurality of upper nanosheets in the first horizontal direction; and
a third active cut that extends into each of the third plurality of bottom nanosheets and the third plurality of upper nanosheets in the vertical direction and is on the upper surface of the lower interlayer insulating layer.

20. A semiconductor device comprising:
a lower interlayer insulating layer that extends in each of a first horizontal direction and a second horizontal direction that intersects the first horizontal direction;
a plurality of bottom nanosheets that are stacked and spaced apart from each other in a vertical direction that is perpendicular to the first horizontal direction and the second horizontal direction, wherein the plurality of bottom nanosheets are on the lower interlayer insulating layer;
a plurality of upper nanosheets that are spaced apart from the plurality of bottom nanosheets in the vertical direction, wherein the plurality of upper nanosheets are stacked and spaced apart from each other in the vertical direction;
an upper isolation layer between an uppermost nanosheet of the plurality of bottom nanosheets and a lowermost nanosheet of the plurality of upper nanosheets,
a bottom gate electrode that extends in the second horizontal direction and is on the lower interlayer insulating layer, wherein the bottom gate electrode at least partially surrounds the plurality of bottom nanosheets;
an upper gate electrode that extends in the second horizontal direction and is on an upper surface of the bottom gate electrode, wherein the upper gate electrode is spaced apart from the bottom gate electrode in the vertical direction, and wherein the upper gate electrode at least partially surrounds the plurality of upper nanosheets;
a bottom capping pattern that is between the lower interlayer insulating layer and the bottom gate electrode, wherein the bottom capping pattern is in contact with a bottom surface of the bottom gate electrode;
an active cut that extends into each of the bottom capping pattern, the bottom gate electrode and the plurality of bottom nanosheets in the vertical direction, wherein the active cut is on an upper surface of the lower interlayer insulating layer, wherein the active cut is spaced apart from the upper gate electrode in the vertical direction, wherein the active cut at least partially overlaps each of the upper gate electrode and the plurality of upper nanosheets in the vertical direction, and wherein a bottom surface of the active cut is coplanar with a bottom surface of the bottom capping pattern;
a gate isolation layer that is between an upper surface of the active cut and a bottom surface of the upper gate electrode and is on sidewalls of the upper isolation layer;
a first gate cut that extends in the first horizontal direction and is on a first sidewall of the upper gate electrode; and
a second gate cut that extends in the first horizontal direction and is on a second sidewall of the upper gate electrode opposite to the first sidewall of the upper gate electrode,
wherein the first sidewall and the second sidewall of the active cut in are in contact with each of the first gate cut and the second gate cut, respectively, and
wherein a width of the upper surface of the active cut in the first horizontal direction is less than a width of the bottom surface of the active cut in the first horizontal direction.
